(19) United States
(12) Patent Application Publication
(10) Pub. No.: US 2023/0227997 A1
(43) Pub. Date: Jul. 20, 2023

(54) METHOD FOR WASHING ALUMINUM NITRIDE SINGLE CRYSTAL SUBSTRATE, METHOD FOR PRODUCING ALUMINUM NITRIDE SINGLE CRYSTAL LAYERED BODY, AND METHOD FOR PRODUCING ALUMINUM NITRIDE SINGLE CRYSTAL SUBSTRATE, AND ALUMINUM NITRIDE SINGLE CRYSTAL SUBSTRATE

(71) Applicant: TOKUYAMA CORPORATION, Shunan-shi, Yamaguchi (JP)

(72) Inventors: Masayuki FUKUDA, Shunan-shi (JP); Hiroshi FURUYA, Shunan-shi (JP)

(73) Assignee: TOKUYAMA CORPORATION, Shunan-shi, Yamaguchi (JP)

(21) Appl. No.: 18/018,446

(22) PCT Filed: Aug. 4, 2021
(86) PCT No.: PCT/JP2021/028965

§ 371 Date: Jan. 27, 2023

(30) Foreign Application Priority Data
Aug. 4, 2020 (JP) 2020-132701

(51) Int. Cl. C30B 25/18; C30B 29/40; C30B 33/00; B08B 1/00; B08B 3/04; H01L 21/02

(52) U.S. Cl. CPC C30B 25/186; B08B 1/001; B08B 3/04; C30B 29/403; C30B 33/00; H01L 21/02052

(57) ABSTRACT

A method for washing an aluminum nitride single crystal substrate, the aluminum nitride single crystal substrate including: an aluminum-polar face; and a nitrogen-polar face opposite to the aluminum-polar face, the method including: (a) scrubbing a surface of the nitrogen-polar face.

### TECHNICAL FIELD

The present invention relates to a novel method for producing an aluminum nitride single crystal substrate; specifically, to a method for producing an aluminum nitride single crystal substrate preferable for a base substrate for iteratively producing aluminum nitride single crystal layers with stable crystal qualities.

### BACKGROUND ART

Group III nitride semiconductors containing aluminum (Al) (AlₓGa_{y}In_{z}N, x + y + z = 1, 0 < x ≤ 1, 0 ≤ y ≤1, and 0 ≤ z ≤1) are expected to be materials from which highly efficient ultraviolet light emitting devices can be produced since having a direct band gap structure in an ultraviolet region corresponding to 200 nm to 360 nm in wavelength. Such a group III nitride semiconductor device is produced by crystal growth of a group III nitride semiconductor thin film over a single crystal substrate by a vapor phase epitaxy method such as metal organic chemical vapor deposition (MOCVD), molecular beam epitaxy (MBE), and hydride vapor phase epitaxy (HVPE).

Any aluminum nitride single crystal substrate obtained by a known crystal growth method such as HVPE and sublimation-recrystallization is used as a single crystal substrate over which crystal growth of the group III nitride semiconductor thin film is achieved. A single crystal substrate excellent in UV-light transparency is preferable for a single crystal substrate for producing an ultraviolet light emitting device; for example, an aluminum nitride single crystal substrate obtained by HVPE (for example, see patent literature 1) is preferably used.

When an aluminum nitride single crystal is grown by HVPE, any aluminum nitride single crystal substrate prepared by physical vapor deposition such as sublimation-recrystallization is preferably used for a base substrate for the crystal growth by HVPE in view of reducing the dislocation density of the grown crystal and in view of improving UV-light transparency (patent literature 2).

An aluminum nitride single crystal produced by a vapor phase epitaxy method such as sublimation-recrystallization is usually in the form of an ingot. This ingot-shaped aluminum nitride single crystal is sliced off an aluminum nitride single crystal substrate having a predetermined thickness by a cutting means such as a wire saw. When the substrate is sliced off, the crystallin structure of the surface of the substrate is disturbed. Thus, usually, the surface of the substrate is processed to be an ultra-flat face by a polishing means such as chemical mechanical polishing (CMP) with an abrasive such as a colloidal silica in order to use the substrate as a single crystal substrate for crystal growth (this substrate is also referred to as a “base substrate”). The substrate having the surface of an ultra-flat face enables a single crystal layer to be easily layered thereover, so that a high-quality single crystal layer can be obtained. The aluminum nitride single crystal substrate has an aluminum-polar face, and a nitrogen-polar face opposite to the aluminum-polar face. When the aluminum nitride single crystal substrate is used as a base substrate, usually, an aluminum nitride single crystal is grown over the aluminum-polar face.

The surface of a base substrate used for crystal growth is preferably clean without foreign substances such as fine particles; generally, is washed by a known method right before subjecting to crystal growth. For example, it is proposed that a crystalline growth face (that is, the aluminum-polar face) of the aluminum nitride single crystal substrate is washed by scrubbing with an alkaline aqueous solution (patent literature 3).

The aluminum nitride single crystal substrate obtained in such a way can be used for producing a device, as a layered body formed by depositing an aluminum nitride single crystal layer over a base substrate. In addition, one may separate this aluminum nitride single crystal substrate into the base substrate and the aluminum nitride single crystal layer, which was layered over the base substrate, and use the separated aluminum nitride single crystal layer for producing a group III nitride semiconductor device. Further, it is also proposed that the surface of the separated base substrate is processed to be an ultra-flat face by polishing by CMP, and thereafter, this base substrate is reused as a base substrate for growing an aluminum nitride single crystal (see patent literature 4).

### CITATION LIST

### Patent Literature

Patent Literature 1: JP 5904470 B2
Patent Literature 2: JP 5931737 B2
Patent Literature 3: WO 2016/039116 A1
Patent Literature 4: WO 2017/164233 A1

### SUMMARY OF INVENTION

### Technical Problem

Generally, the crystal quality of a grown aluminum nitride single crystal layer tends to be influenced by the quality of a base substrate when the aluminum nitride single crystal layer is grown by HVPE over an aluminum nitride single crystal substrate that is used as the base substrate. Therefore, the method disclosed in patent literature 4, where the same base substrate is iteratively used, is an effective method in view of efficiently producing aluminum nitride single crystal layers with stable crystal qualities and/or in view of production costs of aluminum nitride single crystal layers.

However, it was found by the researches of the inventors of the present invention that: when the base substrate is iteratively used to produce aluminum nitride single crystal layers, the base substrate cracks during the production, or faults in crystal growth caused by the base substrate occur, and as a result, it may be impossible to produce aluminum nitride single crystal layers with stable and good crystal qualities.

An object of the present invention is to provide an aluminum nitride single crystal substrate preferable for a base substrate for iteratively producing aluminum nitride single crystal layers with stable crystal qualities.

### Solution to Problem

The inventors of the present invention observed a state of a layered body just after the layer had grown: the layered body was formed by growing, by HVPE, an aluminum nitride single crystal layer over an aluminum nitride single crystal substrate used as a base substrate. As a result, it was found that: no foreign substances were confirmed on the growth surface (an aluminum-polar face) after growth, whereas a large amount of foreign substances adhered to a face opposite to the growth surface, that is, a nitrogen-polar face of the base substrate. This layered body was separated into the base substrate and the grown aluminum nitride single crystal layer, and the growth surface of the separated base substrate (that is, the aluminum-polar face) was mirror-polished to grow an aluminum nitride single crystal again by HVPE. It was then confirmed that many pits were formed in the opposite face (that is, the surface of the nitrogen-polar face of the base substrate) after the crystal growth. In addition the nitrogen-polar face of the base substrate before the crystal growth was compared with that after the crystal growth; as a result, it was confirmed that places where foreign substances remained before the crystal growth were the same as places where pits were formed after the crystal growth in good correlation. Further, as a result of iterative use of the base substrate, where pits were formed in the nitrogen-polar face, as a base substrate for an aluminum nitride single crystal layer, it was also found that: the larger the number of times of the iteration was, the deeper the pits were, so that the pits penetrated through the entire base substrate.

It was suggested from these findings that foreign substances remaining on the surface of the nitrogen-polar face of the aluminum nitride single crystal substrate, which was used as a base substrate before the crystal growth, caused pits to be formed. Thus, the inventors of the present invention studied for a method for removing foreign substances present on the nitrogen-polar face of the substrate. As a result, they found that foreign substances on the surface of the nitrogen-polar face could be removed by scrubbing the surface of the nitrogen-polar face of the aluminum nitride single crystal substrate. They grew an aluminum nitride single crystal layer by HVPE over the aluminum-polar face of the aluminum nitride single crystal substrate having the nitrogen-polar face, which was scrubbed, as the base substrate; and as a result, succeeded suppression of the formation of pits in the nitrogen-polar face of the base substrate. Further, the inventors of the present invention found that aluminum nitride single crystal layers with good crystal qualities can be stably produced by scrubbing, as described above, the nitrogen-polar face of the base substrate after the aluminum nitride single crystal layer over the base substrate is separated from the base substrate to grow an aluminum nitride single crystal layer again by HVPE even when the same base substrate is iteratively used.

A first aspect of the present invention is a method for washing an aluminum nitride single crystal substrate, the aluminum nitride single crystal substrate comprising:
an aluminum-polar face; and
a nitrogen-polar face opposite to the aluminum-polar face, the method comprising:
   (a) scrubbing a surface of the nitrogen-polar face.

In the first aspect of the present invention, the step (a) may comprise:
making a polymer material absorb a washing liquid, wherein the polymer material is less hard than the aluminum nitride single crystal; and
scrubbing the surface of the nitrogen-polar face with the polymer material retaining the washing liquid.

In the first aspect of the present invention, preferably, water or an aqueous solution each having a pH of 4 to 10 is used as the washing liquid in the step (a).

A second aspect of the present invention is a method for producing an aluminum nitride single crystal layered body, the method comprising, in the sequence set forth:
(b) washing a first aluminum nitride single crystal substrate by the method according to the first aspect of the present invention; and
(c) growing a first aluminum nitride single crystal layer over a first base substrate by a vapor phase epitaxy method, wherein the first aluminum nitride single crystal substrate is used as the first base substrate.

In the second aspect of the present invention, preferably, the first aluminum nitride single crystal layer is grown, in the step (c), over an aluminum-polar face of the first base substrate.

A third aspect of the present invention is a method for producing an aluminum nitride single crystal substrate, the method comprising, in the sequence set forth:
(d) obtaining a first aluminum nitride single crystal layered body by the method according to the second aspect of the present invention;
(e) separating the first aluminum nitride single crystal layered body into a second base substrate and a second aluminum nitride single crystal layer, wherein the second base substrate comprises at least part of the first base substrate, and wherein the second aluminum nitride single crystal layer comprises at least part of the first aluminum nitride single crystal layer; and
(f) polishing the second aluminum nitride single crystal layer, to obtain a second aluminum nitride single crystal substrate.

In the third aspect of the present invention, preferably, the second base substrate in the step (e) comprises:
the first base substrate; and
part of the first aluminum nitride single crystal layer layered over the first base substrate.

A fourth aspect of the present invention is a method for producing an aluminum nitride single crystal layered body, the method comprising, in the sequence set forth:
(d) obtaining a first aluminum nitride single crystal layered body by the method according to the second aspect of the present invention;
(e) separating the first aluminum nitride single crystal layered body into a second base substrate and a second aluminum nitride single crystal layer, wherein the second base substrate comprises at least part of the first base substrate, and wherein the second aluminum nitride single crystal layer comprises at least part of the first aluminum nitride single crystal layer;
(g) polishing a surface of the second base substrate;
(h) washing the second base substrate by the method according to any one of claims 1 to 3; and
(i) growing a third aluminum nitride single crystal substrate over the second base substrate by a vapor phase epitaxy method.

In the fourth aspect of the present invention, preferably, the second base substrate in the step (e) comprises:
the first base substrate; and
part of the first aluminum nitride single crystal layer layered over the first base substrate.

In the fourth aspect of the present invention, preferably, the third aluminum nitride single crystal layer is grown over an aluminum-polar face of the second base substrate.

A fifth aspect of the present invention is a method for producing an aluminum nitride single crystal substrate, the method comprising, in the sequence set forth:
(j) obtaining a second aluminum nitride single crystal layered body by the method according to the fourth aspect of the present invention;
(k) separating the second aluminum nitride single crystal layered body into a third base substrate and a fourth aluminum nitride single crystal layer, wherein the third base substrate comprises at least part of the second base substrate, and wherein the fourth aluminum nitride single crystal layer comprises at least part of the third aluminum nitride single crystal layer; and
(l) polishing the fourth aluminum nitride single crystal layer, to obtain a third aluminum nitride single crystal substrate.

In the fifth aspect of the present invention, preferably, the third base substrate in the step (k) comprises:
the second base substrate; and
part of the third aluminum nitride single crystal layer layered over the second base substrate.

A sixth aspect of the present invention is an aluminum nitride single crystal substrate comprising:
an aluminum-polar face; and
a nitrogen-polar face opposite to the aluminum-polar face,
wherein a number density of foreign substances having a longer diameter of no less than 10 µm on a surface of the nitrogen-polar face per unit area is 0.01 to 3 pcs/mm².

In the sixth aspect of the present invention, preferably, the nitrogen-polar face has a surface roughness of 1 to 8 nm in terms of arithmetic average roughness Ra.

### Advantageous Effects of Invention

According to the method for washing an aluminum nitride single crystal substrate according to the first aspect of the present invention, foreign substances adhering to the surface of a nitrogen-polar face of an aluminum nitride single crystal substrate can be removed by scrubbing the nitrogen-polar face, which enables an aluminum nitride single crystal substrate in a state suitable for a base substrate for crystal growth to be obtained.

According to the method for producing an aluminum nitride single crystal layered body according to the second aspect of the present invention, an aluminum nitride single crystal layer is layered over a base substrate by a vapor phase epitaxy method, wherein an aluminum nitride single crystal substrate obtained by the washing method according to the first aspect of the present invention is used as the base substrate, which enables an aluminum nitride single crystal layered body having an opposite face (nitrogen-polar face) where formation of pits is suppressed to be produced.

According to the method for producing an aluminum nitride single crystal substrate according to the third aspect of the present invention, an aluminum nitride single crystal substrate is obtained from a first aluminum nitride single crystal layer (growth layer) of the aluminum nitride single crystal layered body obtained by the method according to the second aspect of the present invention, which enables an aluminum nitride single crystal substrate with a good crystal quality to be stably produced.

According to the method for producing an aluminum nitride single crystal layered body according to the fourth aspect of the present invention, an aluminum nitride single crystal layer is grown over a second base substrate again by a vapor phase epitaxy method after the nitrogen-polar face of the second base substrate separated from the first aluminum nitride single crystal layered body obtained by the method according to the second aspect of the present invention is washed by the method according to the first aspect of the present invention, which enables an aluminum nitride single crystal layered body comprising an aluminum nitride single crystal layer (growth layer) with a good crystal quality to be stably produced even when the same base substrate is iteratively used.

According to the method for producing an aluminum nitride single crystal substrate according to the fifth aspect of the present invention, an aluminum nitride single crystal substrate is obtained from a third aluminum nitride single crystal layer (growth layer) of the second aluminum nitride single crystal layered body obtained by the method according to the fourth aspect of the present invention, which enables an aluminum nitride single crystal substrate with a good crystal quality to be stably produced.

The aluminum nitride single crystal substrate according to the sixth aspect of the present invention can be obtained by subjecting an aluminum nitride single crystal substrate to the method according to the first aspect of the present invention. The aluminum nitride single crystal substrate according to the sixth aspect of the present invention is an aluminum nitride single crystal substrate in a state suitable for a base substrate for crystal growth, and can suppress formation and extension in the depth direction of pits in a nitrogen-polar face thereof (base substrate) when an aluminum nitride single crystal layer (growth layer) is grown over the aluminum nitride single crystal substrate (base substrate) by a vapor phase epitaxy method.

The inventors of the present invention consider the reason why the present invention brings about the above effects as follows. The nitrogen-polar face of aluminum nitride is inferior to the aluminum-polar face thereof in chemical stability. As one possibility, it is considered that foreign substances are decomposed by heat during crystal growth when remaining on a surface of a nitrogen-polar face, and the nitrogen-polar face is chemically etched by degradation products, to form pits. As another possibility, it is considered that: an aluminum nitride single crystal substrate and a susceptor where the substrate is disposed are brought into contact with each other at places where foreign substances are present on the opposite face, which leads to a place where thermal resistance is locally low between the susceptor and the opposite face of the substrate, and as a result, etching by heat progresses.

It is then considered that further progress of etching due to the function of an abrasive and/or a washing liquid in a polishing step to be performed later causes the pits formed in the nitrogen-polar face to be larger and deeper. Iterative use of the substrate where such pits are formed as a base substrate is considered to lead extension of the pits formed in the opposite face (nitrogen-polar face) to the surface (aluminum-polar face) to cause reuse of the substrate to be impossible. In contrast, according to each of the production methods according to the present invention, scrubbing the nitrogen-polar face enables foreign substances adhering to the nitrogen-polar face to be removed. Thus, each of the production methods according to the present invention is considered to enable the formation of pits in the nitrogen-polar face to be suppressed when the aluminum nitride single crystal layer is grown over the base substrate by a vapor phase epitaxy method.

### BRIEF DESCRIPTION OF DRAWINGS

FIG. 1 is a flowchart illustrating a method S10 for washing an aluminum nitride single crystal substrate according to one embodiment;

FIG. 2 is a flowchart illustrating a method S100 for producing an aluminum nitride single crystal layered body according to one embodiment;

FIG. 3 schematically illustrates the production method S100 with cross sections;

FIG. 4 is a flowchart illustrating a method S200 for producing an aluminum nitride single crystal substrate according to one embodiment;

FIG. 5 is a flowchart illustrating a method S300 for producing an aluminum nitride single crystal layered body according to another embodiment;

FIG. 6 schematically illustrates the production methods S200 and S300 with cross sections;

FIG. 7 is a flowchart illustrating a method S400 for producing an aluminum nitride single crystal substrate according to another embodiment;

FIG. 8 schematically illustrates the production method S400 with cross sections;

FIG. 9 schematically illustrates arrangement of nine measurement points on a substrate when the number of foreign substances on a surface of a nitrogen-polar face per unit area is measured, and shows the nine measurement points superposed on a plan view of a first aluminum nitride single crystal substrate 10;

FIG. 10 illustrates the center of a substrate when the planar shape of the substrate is a partially distorted circle, with a plan view of an aluminum nitride single crystal substrate 30 according to another embodiment; and

FIG. 11 illustrates the center of a substrate when the planar shape of the substrate is a partially distorted regular polygon, with a plan view of an aluminum nitride single crystal substrate 40 according to another embodiment.

### DESCRIPTION OF EMBODIMENTS

Hereinafter the embodiments of the present invention will be described in more detail with reference to the drawings. The present invention is not restricted to these embodiments. The drawings do not always represent precise measurements. In the drawings, some reference sings may be omitted. Expression “A to B” concerning numeral values A and B means “no less than A and no more than B” unless otherwise specified in this description. If a unit is added only to the numeral value B in such expression, this unit shall be applied to the numeral value A as well. In this description, a word “or” means a logical sum unless otherwise specified. In this description, expression “E₁ and/or E₂” concerning elements E₁ and E₂ shall be equivalent to “E₁, or E₂, or the combination thereof”, and expression “E₁, ..., and/or E_{N}” concerning n elements E₁, ..., Eᵢ, ..., E_{N} (N is an integer of 3 or more) shall be equivalent to “E₁, ..., or Eᵢ, ..., or E_{N}, or any combination thereof” (i is a variable that can take any of integers satisfying 1 < i < N). In this description, “group III” concerning elements shall mean any elements in group 13 of the periodic table. In this description, an “x-ray rocking curve” means an “X-ray omega rocking curve”. In this description, “half width” shall mean “full width at half maximum” unless otherwise specified.

### 1. Method for Washing Aluminum Nitride Single Crystal Substrate

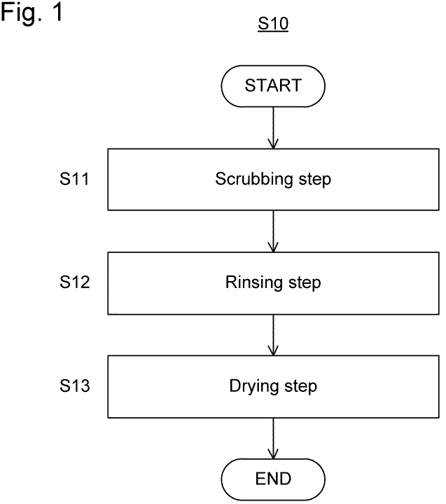

FIG. 1 is a flowchart illustrating a method S10 for washing an aluminum nitride single crystal substrate according to one embodiment of the present invention (hereinafter may be referred to as the “washing method S10”). The washing method S10 comprises, in the sequence set forth: the step S11 of (a) scrubbing a surface of a nitrogen-polar face of an aluminum nitride single crystal substrate (hereinafter may be referred to as the “scrubbing step S11”); the step S12 of rinsing the aluminum nitride single crystal substrate with water (hereinafter may be referred to as the “rinsing step S12”); and the step S13 of drying the aluminum nitride single crystal substrate (hereinafter may be referred to as the “drying step S13”). The aluminum nitride single crystal substrate has an aluminum-polar face, and the nitrogen-polar face opposite to the aluminum-polar face. The scrubbing step S11 is a step of scrubbing the surface of the nitrogen-polar face of the aluminum nitride single crystal substrate, which is prepared in advance. Various foreign substances may adhere to the nitrogen-polar face of the aluminum nitride single crystal substrate. Examples of such foreign substances include: inorganic matters such as shaved substrate chips and abrasives used for polishing when the polishing is performed by CMP; organic matters such as a wax used for fixing the substrate when polishing is performed; particles that were in the environment but are adhered after the polishing by CMP; and sebaceous matters adhered when the substrate is handled. These foreign substances usually have a diameter of approximately 0.1-100 µm each. According to the washing method S10, foreign substances as described above on the nitrogen-polar face can be removed by washing the nitrogen-polar face of the aluminum nitride single crystal substrate in the scrubbing step S11. When an aluminum nitride single crystal substrate is used as a base substrate to grow an aluminum nitride single crystal layer over this base substrate by a vapor phase epitaxy method, an aluminum-polar face is usually used as a growth face for the aluminum nitride single crystal layer. That is, usually, an aluminum nitride single crystal layer is grown over an aluminum-polar face of a base substrate. For this, it has been recognized that smoothness of a surface of an aluminum-polar face of a base substrate which is a growth face is important for obtaining a high-quality aluminum nitride single crystal layer, and thus, foreign substances have been removed. Meanwhile, no attention has been paid in particular so far to surface properties of a nitrogen-polar face that is not used as a growth face. According to the washing method S10, foreign substances adhered to the nitrogen-polar face can be efficiently removed by scrubbing the nitrogen-polar face of the aluminum nitride single crystal substrate.

### Aluminum Nitride Single Crystal Substrate

The aluminum nitride single crystal substrate used for the method according to the present invention is not particularly limited. For example, any aluminum nitride single crystal substrate produced by a known method such as HVPE and a sublimation method can be used without particular restrictions. According to the sublimation method among the above-described known methods, usually, an ingot-shaped thick aluminum nitride single crystal is obtained. For example, an aluminum nitride single crystal substrate having a desired thickness which is cut out from this ingot-shaped aluminum nitride single crystal by a known cutting means such as a wire saw and is processed by a known grinding method and/or a known polishing method can be used. In the washing method S10, the scrubbing step S11 to be described later may be performed on the prepared aluminum nitride single crystal substrate as it is. Preferably, however, the scrubbing step S11 is performed on the aluminum nitride single crystal substrate after the surface of the substrate is polished by, for example, CMP with an abrasive such as a colloidal silica to be processed to be ultra-flat. In particular, foreign substances derived from an abrasive, a wax, etc. that are used when the polishing is performed may adhere to and remain on the aluminum nitride single crystal substrate polished by CMP. According to the washing method S10, such foreign substances can be effectively removed, which causes the effects of the present invention to be more outstandingly demonstrated. Polishing of the surface of the substrate by CMP or the like may be performed only on either one face, or both faces of the aluminum-polar face and the nitrogen-polar face of the aluminum nitride single crystal substrate.

The aluminum nitride single crystal substrate used in the method according to the present invention comprises the aluminum-polar face ((001) face), and the nitrogen-polar face ((00-1) face) opposite to this aluminum-polar face.

The aluminum-polar face may have an offset angle which is 0.00° to 1.00°, more preferably 0.05° to 0.70°, and further preferably 0.10° to 0.40° from the surface where the aluminum nitride single crystal layer is grown. Such an offset angle allows a thicker aluminum nitride single crystal layer to be grown over the aluminum-polar face. This offset angle can be adjusted during the above-described polishing by CMP.

Preferably, an X-ray omega rocking curve of a (103) face has a half width of no more than 200 arcsec: this X-ray omega rocking curve is measured under a condition that an incident angle between an incident X-ray and the aluminum-polar face of the aluminum nitride single crystal substrate is no more than 4°, and more preferably no more than 2°. In view of current measurement techniques, the lower limit of the incident angle between the incident X-ray and the main aluminum-polar face is 0.1°. The value of the half width of the X-ray omega rocking curve of the above crystal face reflects the crystal quality in the neighborhood of the crystal surface since the aluminum nitride single crystal substrate is irradiated with an X-ray at a narrow incident angle. In view of improving the quality of the aluminum nitride single crystal layer layered over the aluminum nitride single crystal substrate, the X-ray omega rocking curve of the crystal face more preferably has a half width of no more than 100 arcsec, and further preferably has a half width of no more than 50 arcsec. While a narrower half width is more preferable, the half width is preferably no less than 10 arcsec in view of industrial production of the aluminum nitride single crystal substrate.

In the measurement of the X-ray omega rocking curve of the crystal face, an X-ray source monochromated by being diffracted twice by the (220) face of a germanium single crystal is preferably used since the means for monochromation of an X-ray source affects resolution of the measured half-width.

In view of growing a thicker aluminum nitride single crystal layer over the aluminum nitride single crystal substrate, the dislocation density in the aluminum-polar face of the aluminum nitride single crystal substrate is preferably no more than 10⁶ cm⁻², more preferably no more than 10⁵ cm⁻², further preferably no more than 10⁴ cm⁻², and especially preferably no more than 10³ cm⁻ ². While a lower dislocation density is more preferable, the lower limit of the dislocation density in the aluminum-polar face can be, for example, no less than 10 cm⁻² in view of industrial production of the aluminum nitride single crystal substrate. In the present invention, the value of the etch pit density is substituted for the value of the dislocation density. The etch pit density is a number average density per unit area measured by: etching the aluminum nitride single crystal substrate in molten alkali hydroxides of sodium hydroxide and potassium hydroxide to form pits at dislocations; counting the number of the pits formed in the surface of the aluminum nitride single crystal substrate by observation by means of an optical microscope; and dividing the number of the counted pits by an observed area.

The shape of the surface of the aluminum nitride single crystal substrate may be any of a round, a quadrangular, or an indefinite shape; and the area thereof is preferably 100 to 10000 mm². When having a round shape, the aluminum nitride single crystal substrate preferably has a diameter of no less than 1 inch (25.4 mm), and further preferably has a diameter of no less than 2 inches (50.8 mm). The thickness of the aluminum nitride single crystal substrate may be determined within such a range that the aluminum nitride single crystal substrate does not break due to insufficient strength when the aluminum nitride single crystal layer to be described later is grown. Specifically, the thickness of the aluminum nitride single crystal substrate is, for example, preferably 50 to 2000 µm, and more preferably 100 to 1000 µm.

The aluminum-polar face of the aluminum nitride single crystal substrate is not especially limited other than the above, but the surface roughness (arithmetic average roughness Ra) thereof is preferably 0.05 to 0.5 nm. In addition, preferably, an atomic step is observed by observation by means of an atomic force microscope or a scanning probe microscope having a field of approximately 1 µm×1 µm. The surface roughness can be adjusted by polishing by CMP as well as in the polishing step described in detail below. The surface roughness (arithmetic average roughness Ra) can be measured by means of a white-light interferometric microscope after foreign substances and contaminants on the surface of the substrate are removed. In this description, the measurement of the surface roughness (arithmetic average roughness Ra) of the aluminum nitride single crystal substrate by means of a white-light interferometric microscope can be performed according to the following procedures. The field (58800 µm² (280 µm×210 µm)) set at the center of the substrate is observed by means of a white-light interferometric microscope (NewView (registered trademark) 7300 manufactured by Zygo Corporation) with an object lens with a magnifying power of 50. The white-light interferometric microscope (NewView (registered trademark) 7300 manufactured by Zygo Corporation) has a function of automatically measuring and calculating the surface roughness of a field. The arithmetic average roughness Ra can be automatically measured and calculated along a measurement line that is automatically set at the center of the field.

The radius of curvature of the surface profile of the aluminum-polar face of the aluminum nitride single crystal substrate is not specifically limited, either, but is preferably within the range of 0.1 to 10000 m.

### Scrubbing Step S11

In the washing method S10, the nitrogen-polar face of the aluminum nitride single crystal substrate, which is prepared in advance, is scrubbed. Examples of foreign substances adhered to the surface of the aluminum nitride single crystal substrate include: inorganic matters such as shaved substrate chips and abrasives used for polishing when the polishing is performed by CMP; organic matters such as a wax used for fixing the substrate when polishing is performed; particles that were in the environment but are adhered after the polishing step by CMP; and sebaceous matters adhered when the substrate is handled. The size of these foreign substances depends on the method of vapor phase growth, the polishing method, etc. Usually, the foreign substances have a diameter of approximately 0.1-100 µm each.

When an aluminum nitride single crystal substrate is used as a base substrate to grow an aluminum nitride single crystal layer over the base substrate by a vapor phase epitaxy method, an aluminum-polar face is usually used as a growth face for the aluminum nitride single crystal layer. For this, it has been recognized that smoothness of a surface of an aluminum-polar face of a base substrate which is a growth face is important for obtaining a high-quality aluminum nitride single crystal layer, and thus, foreign substances have been removed. Meanwhile, no attention has been paid in particular so far to surface properties of a nitrogen-polar face that is not used as a growth face. In the washing method S10, foreign substances as described above on the nitrogen-polar face of the aluminum nitride single crystal substrate can be removed by scrubbing the nitrogen-polar face in the scrubbing step S11.

In the scrubbing step S11, only the nitrogen-polar face of the aluminum nitride single crystal substrate, or both the nitrogen-polar face and the aluminum-polar face thereof may be scrubbed. In particular, preferably, both the nitrogen-polar face and the aluminum-polar face are scrubbed when the aluminum-polar face was polished by CMP since foreign substances as described above also adhere to the surface of the aluminum-polar face.

When both the nitrogen-polar face and the aluminum-polar face of the aluminum nitride single crystal substrate are scrubbed, preferably, the nitrogen-polar face is scrubbed first before the aluminum-polar face is scrubbed. When the nitrogen-polar face is scrubbed, the substrate is usually arranged in such a manner that the aluminum-polar face is on the bottom side. It is necessary to pay attention to the aluminum-polar face for suppressing contamination during the washing, and formation of flaws, since the aluminum-polar face is a face where crystal growth is performed after the washing. When the scrubbing is performed by means of a currently commercially available scrub cleaning apparatus, mostly, the substrate is fixed to a stage by means of a vacuum chuck. Such a way of setting the substrate, however, may lead to damage such as flaws to the aluminum-polar face. Therefore, preferably, the nitrogen-polar face is scrubbed manually according to the procedures to be described later instead of using a scrub cleaning apparatus with a vacuum chuck to fix the substrate.

### Washing Liquid Used for Scrubbing

In the scrubbing step S11, any known washing liquid can be used as a washing liquid (scrubbing liquid). Specific examples of such a washing liquid include: neutral liquids such as ultrapure water, acetone, and ethanol; and any washing liquid obtained by adjusting the pH of an acidic or alkaline washing liquid on the market to be within a desired range. As the washing liquid herein, one washing liquid may be used alone, or two or more washing liquids may be used in combination. When two or more washing liquids are used in combination, different washing liquids may be successively used, or plural washing liquids may be mixed to be used. As the washing liquid herein, water or aqueous solution can be preferably used.

As a washing liquid of an aqueous solution herein, any commercially available washing liquid for a semiconductor substrate can be used. One example of an aqueous solution that can be used as the washing liquid in the scrubbing step S11 is an aqueous solution containing at least one component selected from a surfactant, a complexing agent, and a pH adjustor.

Examples of a surfactant herein include nonionic surfactants, anionic surfactants, and cationic surfactants. As the surfactant herein, one surfactant may be used alone, or two or more surfactants may be used in combination.

Examples of a nonionic surfactant herein include polyoxyalkylene alkyl ether (e.g., alkyl carbitol having a C4-18 alkyl group, such as diethylene glycol monobutyl ether, and diethylene glycol monododecyl ether; ethylene oxide adducts of a C8-18 alcohol; and ethylene oxide adducts of an alkylphenol having a C1-12 alkyl group), ethylene oxide adducts of polypropylene glycol (number average molecular weight: 200-4000), complete esters of phosphoric acid and a polyoxyalkylene alkyl ether, complete esters of sulfuric acid and a polyoxyalkylene alkyl ether, fatty acid esters of glycerin, fatty acid (C8-24) esters of a polyhydric alcohol (having 2-8 or more hydroxyl groups) (e.g., sorbitan monolaurate, and sorbitan monooleate), and fatty acid alkanolamides (e.g., lauric acid monoethanolamide, and lauric acid diethanolamide).

Examples of an anionic surfactant herein include alkyl sulfonic acid having a C8-18 alkyl group (e.g., dodecanesulfonic acid), alkylbenzenesulfonic acid having a C8-18 alkyl group (e.g., dodecylbenzenesulfonic acid), alkyl diphenyl ether sulfonate, alkylmethyl taurine acid, sulfosuccinic acid diesters, monoesters of sulfuric acid and a polyoxyalkylene alkyl ether, fatty acids having 10 or more carbon atoms, partial esters of phosphoric acid and a polyoxyalkylene alkyl ether, partial esters of phosphoric acid and a C8-18 alcohol, polyoxyalkylene alkyl ether acetic acid (e.g., polyoxyethylene lauryl ether acetic acid, and polyoxyethylene tridecyl ether acetic acid), polymer type anionic surfactants (e.g., polystyrenesulfonic acid, styrene-styrene sulfonic acid copolymers, 2-(meth)acryloylamio-2,2-dimethylethanesulfonic acid-(meth)acrylic acid copolymers, naphthalene sulfonic acid-formamide condensates, benzoic acid-formaldehyde condensates, poly (meth)acrylates, (meth)acrylic acid-maleic acid copolymers, and carboxy methylcellulose), and salts thereof (e.g., metal salts such as alkali metal salts, ammonium salts, and primary or secondary or tertiary amine salts). In this description, “(meth)acryl” means “acryl and/or methacryl”, and “(meth)acrylate” means “acrylate and/or methacrylate”.

Examples of a cationic surfactant herein include tetraalkylammonium halides having a C8-18 alkyl group (e.g., octyltrimethylammonium bromide, and dodecylethyldimethylammonium bromide).

When the washing liquid contains the surfactant, the content of the surfactant can be, for example, 0.0001 to 5 mass% or 0.001 to 2 mass% on the basis of the total mass of the washing liquid.

Examples of a complexing agent herein include complexing agents having an amino group and/or a carboxy group, complexing agents having a phosphonic acid group, and complexing agents having a sulfur atom. As an example of the complexing agent herein, one complexing agent may be used alone, or two or more complexing agents may be used in combination.

Examples of complexing agents having an amino group and/or a carboxy group herein include alkanolamines (e.g., ethanolamine, propanolamine, isopropanolamine, butanolamine, diethanolamine, triethanolamine, dipropanolamine, tripropanolamine, diisopropanolamine, and triisopropanolamine), diamines (e.g., ethylenediamine, diaminopropane, and diaminobutane), amino acid (e.g., glycine, alanine, β-alanine, serine, aspartic acid, glutamic acid, histidine, cysteine, and methionine), aminopolycarboxylic acid (e.g., ethylenediaminetetraacetic acid (EDTA), propylenediaminetetraacetic acid, diethylenetriaminepentaacetic acid (DTPA), triethylenetetraminehexaacetic acid (TTHA), hydroxyethyliminodiacetic acid (HIDA), 1,2-diaminocyclohexanetetraacetic acid (DCTA), nitrilotriacetic acid (NTA), β-alanine diacetic acid, aspartic acid diacetic acid, methylglycinediacetic acid, iminodisuccinic acid, and serine diacetic acid), hydroxycarboxylic acid (e.g., lactic acid, gluconic acid, and gallic acid), dicarboxylic acid (e.g., oxalic acid, malonic acid, succinic acid, maleic acid, tartaric acid, malic acid, glutaric acid, adipic acid, and iminodiacetic acid), polycarboxylic acid (e.g., citric acid, pyromellitic acid, and cyclopentanetetracarboxylic acid), polyhydroxy compounds (e.g., ascorbic acid, and isoascorbic acid), picolinic acid, and salts thereof.

Examples of complexing agents having a phosphonic acid group herein include methylene diphosphonic acid, etidronic acid, amino tri(methylene phosphonic acid), 1-hydroxyethylidene-1,1-diphosphonic acid (HEDP), nitrilotris(methylene phosphonic acid) (NTMP), ethylene diamine tetra(methylene phosphonic acid), hexamethylenediamine tetra(methylene phosphonic acid), propylene diamine tetra(methylene phosphonic acid), diethylene triamine penta(methylene phosphonic acid), triethylene tetramine hexa(methylene phosphonic acid), triaminotriethylamine hexa(methylene phosphonic acid), trans-1,2-cyclohexanediamine tetra(methylenesulfonic acid), glycol ether diamine tetra(methylene phosphonic acid), tetraethylenepentamine hepta(methylene phosphonic acid), metaphosphoric acid, pyrophosphoric acid, tripolyphosphoric acid, hexametaphosphoric acid, and salts thereof.

Examples of complexing agents having a sulfur atom herein include thiols (e.g., cysteine, methanethiol, ethanethiol, thiophenol, and glutathione), and thioethers (e.g., methionine, and dimethyl sulfide), and salts thereof.

When the washing liquid contains the complexing agent, the content of the complexing agent can be, for example, 0.001 to 5 mass% or 0.01 to 2 mass% on the basis of the total mass of the washing liquid.

Example of a pH adjustor herein include inorganic acids (e.g., sulfuric acid, hydrochloric acid, nitric acid, and phosphoric acid), inorganic bases (e.g., alkali metal hydroxides such as sodium hydroxide and potassium hydroxide, and ammonia), organic acids (e.g., various carboxylic acids, sulfonic acids, and phosphonic acids), organic bases (e.g., various amine compounds such as trimethylamine, and triethylamine; alkanolamine compounds; and organic quaternary ammonium hydroxides such as tetramethylammonium hydroxide, tetraethylammonium hydroxide, tetrapropylammonium hydroxide, tetrabutylammonium hydroxide, methyltriethylammonium hydroxide, 2-hydroxyethyltrimethylammonium hydroxide, bis(2-hydroxyethyl)dimethylammonium hydroxide, tris(2-hydroxyethyl)methylammonium hydroxide, and triethyl(2-hydroxyethyl)ammonium hydroxide, and salts thereof; and combinations thereof. As the pH adjustor herein, one pH adjustor may be used alone, or two or more pH adjustors may be used in combination. When having function of both the surfactant and the pH adjustor, a single compound shall contribute to the contents of both the surfactant and the pH adjustor. When having function of both the complexing agent and the pH adjustor, a single compound shall contribute to the contents of both the complexing agent and the pH adjustor.

When the washing liquid contains the pH adjustor, the pH adjustor is incorporated in such a manner that the amount of the pH adjustor causes the pH of the washing liquid to be a desired value. Such a content of the pH adjustor can be, for example, 0.001 to 5 mass% or 0.01 to 2 mass% on the basis of the total mass of the washing liquid.

A nitrogen-polar face of aluminum nitride tends to be inferior to an aluminum-polar face thereof in chemical stability. In the method disclosed in patent literature 3, an alkaline aqueous solution having a concentration of 0.01 to 1 mass% is used as a washing liquid when an aluminum-polar face is scrubbed. This washing liquid has a pH of 11.3 to 13.4. However, when such a high alkaline washing liquid is used as an alkaline washing liquid for a nitrogen-polar face, the surface of the nitrogen-polar face tends to be etched. As a result, the surface of the nitrogen-polar face tends to be rough. Therefore, in view of efficiently removing foreign substances as described above, and in view of efficiently suppressing etching of the nitrogen-polar face, the pH of the washing liquid is preferably 4 to 10, more preferably 7 to 10, and especially preferably 7 to 8.

### Polymer Material Used for Scrubbing

In the scrubbing step S11, the surface of the substrate is scrubbed and cleaned with a polymer material that is less hard than the aluminum nitride single crystal substrate. For the polymer material used in the scrubbing step S11, any material that does not deteriorate because of the washing liquid, and that enables foreign substances to be effectively removed without any damage to the surface of the substrate is preferable. Specific examples of such a polymer material include foams, porous bodies, woven fabrics, nonwoven fabrics, and brushes which are formed from polymers such as melamine resins, polyvinyl alcohol (PVA) resins, polyester resins, and polyamide resins (e.g., nylon (registered trademark)). Examples of foams and porous bodies herein include melamine foams, and PVA sponges. Examples of woven fabrics, nonwoven fabrics, and brushes herein include woven fabrics, nonwoven fabrics, and brushes which are formed from fibers such as polyester resin fibers, and polyamide resin (e.g., nylon (registered trademark)) fibers. As the polymer material used for the scrubbing, any polymer material that is used for scrubbing substrates for semiconductor use can be preferably used.

The polymer material may have any shape according to the method of scrubbing as long as the shape is suitable for removal of foreign substances. For example, when being a foam, the polymer material is preferably in the form of a rectangular parallelepiped, or a cube. These shapes allow the polymer material to be efficiently brought into contact with the surface of the substrate to improve washing effect since the face of the polymer material to be in contact with the surface of the substrate is flat. When being fibrous, the polymer material is preferably in the form of a woven fabric, a nonwoven fabric, or a brush in view of efficient washing. When the polymer material is in the form of a brush, preferably, scrubbing is performed while the washing liquid is supplied since the washing liquid cannot be held in the polymer material.

### Scrubbing of Nitrogen-Polar Face

In the scrubbing step S11, foreign substances adhered to the surface of the substrate is physically removed by scrubbing the surface of the substrate with the polymer material in a state where the surface of the substrate is wet enough with the washing liquid. Any known method can be employed as the method of the scrubbing. Specifically, the substrate can be scrubbed as arranged on a material less hard than the aluminum nitride single crystal substrate. For the material on which the substrate is arranged (that is, the material arranged under the substrate), a high cushioning polymer material is preferable in view of suppressing damage such as flaws on the aluminum-polar face. For example, a porous polymer or a polymeric foam, such as melamine foams and porous polyvinyl alcohol (PVA sponges), can be preferably used.

Preferably, the scrubbing step S11 comprises: making the polymer material absorb the washing liquid, wherein the polymer material is less hard than the aluminum nitride single crystal substrate; and scrubbing the surface of the nitrogen-polar face with the polymer material retaining the washing liquid. More preferably, the scrubbing step S11 comprises: making the polymer material absorb the washing liquid, wherein the polymer material is less hard than the aluminum nitride single crystal substrate; wetting the nitrogen-polar face with the washing liquid; and scrubbing the surface of the nitrogen-polar face with the polymer material retaining the washing liquid. The nitrogen-polar face of the aluminum nitride single crystal substrate can be preferably scrubbed by wetting the nitrogen-polar face enough with the washing liquid, and scrubbing the surface of the substrate with the polymer material retaining the washing liquid. Concerning the method of scrubbing the surface of the substrate, preferably, the polymer material is moved in parallel to (the in-plane direction of) the surface of the substrate in a state where the polymer material is in contact with the surface of the substrate. Specific examples of the way of moving in parallel to the surface of the substrate include a way of moving in one direction only, a way of moving reciprocatively in a certain line, and a way of moving as describing an arc. Among them, a way of moving in one direction only, or a way of moving reciprocatively in a certain line is preferable in view of operational performance. How many times the polymer material is moved as being in contact with the surface of the substrate is not particularly limited, but the times may be suitably determined according to the sizes of the substrate and the polymer material. However, the entire surface of the substrate, and the polymer material preferably come into contact with each other at least five times because the more the number of the times are, the more the effect of the present invention is obtained.

While the surface of the substrate is scrubbed with the polymer material, preferably, the washing liquid is periodically supplied in order for the surface of the substrate and the polymer material not to be dry. Examples of the way of supplying the washing liquid include a way of directly pour the washing liquid over the substrate, and a way of immersing the polymer material in the washing liquid.

The temperature of the washing liquid when the scrubbing is performed is not particularly limited, but is preferably within the range of 10 to 40° C. because the higher the temperature is, the easier etching of the nitrogen-polar face progresses.

### Rinsing Step S12

In the washing method S10, rinsing with water is performed (rinsing step S12) after the scrubbing step S11 in order to prevent the components of the washing liquid from remaining on the surface of the substrate. Ultrapure water is preferably used for the rinsing in view of suppressing adhesion of foreign substances, and in view of improving rinsing effect.

By the rinsing step S12, the washing liquid including foreign substances can be removed from the substrate after the scrubbing step S11, which enables the substrate, from which foreign substances adhered to the nitrogen-polar face thereof is removed, to be obtained. In the rinsing step S12, rinsing in flowing water is preferably performed, and rinsing in flowing water with ultrapure water is more preferably performed.

### Drying Step S13

After the scrubbing (S11) and the rinsing (S12), moisture adhered to the substrate is removed and the substrate is dried (drying step S13). As the way of drying the substrate, any known way such as spin drying, drying by an air blow, and steam drying can be employed without particular restrictions. The dried aluminum nitride single crystal substrate is preferably stored in a clean and well hermetically sealable wafer carrier or the like for avoiding contamination from the outside. Through steps S11 to S13, the washing method S10 is completed.

The above description concerning the present invention shows the washing method S10 of scrubbing and rinsing the nitrogen-polar face of the aluminum nitride single crystal substrate in the steps S11 and S12 as an example. The present invention is not limited to this embodiment. For example, the method for washing the aluminum nitride single crystal substrate can comprise scrubbing the nitrogen-polar face, and thereafter, further scrubbing the aluminum-polar face continuously; or can comprise scrubbing both the nitrogen-polar face and the aluminum-polar face simultaneously. When the nitrogen-polar face of the aluminum nitride single crystal substrate is scrubbed, and thereafter, the aluminum-polar face thereof is continuously scrubbed, it is not necessary to dry moisture adhered to the substrate before the aluminum-polar face is scrubbed. The aluminum-polar face can be scrubbed by a known method such as the method disclosed in patent literature 3. However, the pH of the washing liquid used for scrubbing the aluminum-polar face is preferably within the range of 4 to 10, in view of preventing the washing liquid used for scrubbing the aluminum-polar face from coming around the nitrogen-polar face to etch the surface of the nitrogen-polar face.

After scrubbed, the aluminum-polar face is rinsed in flowing water to remove moisture adhered to the substrate, so that the substrate is dried. As the drying way, any known way such as spin drying, drying by an air blow, and steam drying can be employed without particular restrictions. The dried aluminum nitride single crystal substrate is preferably stored in a clean and well hermetically sealable wafer carrier or the like for avoiding contamination from the outside.

The above description concerning the present invention shows the washing method S10 of performing the rinsing step S12 after the scrubbing step S11 as an example. The present invention is not limited to this embodiment. For example, when the washing liquid is not an aqueous solution but water, the washing method can comprise no rinsing step after the scrubbing step. Preferably, the rinsing step is performed after the scrubbing step even when the washing liquid is water in view of washing away adhered materials on the substrate.

### Washed Aluminum Nitride Single Crystal Substrate

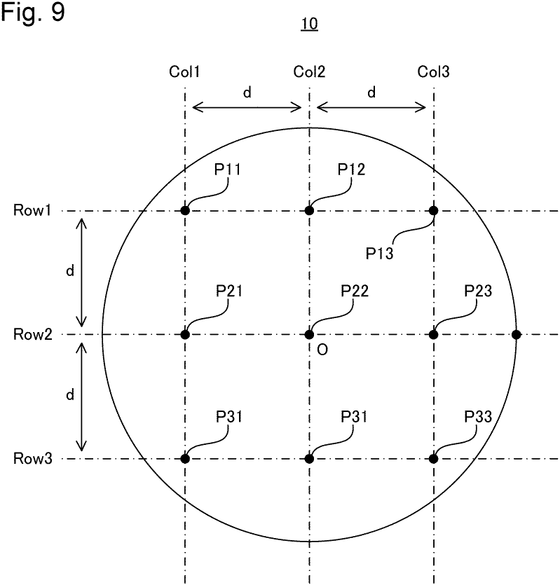

The aluminum nitride single crystal substrate, from which foreign substances on the nitrogen-polar face are removed, can be obtained by the washing method S10. The number of foreign substances remaining on the surface of the aluminum nitride single crystal substrate obtained like this way is reduced so much. The number (number density) of foreign substances having a longer diameter of no less than 10 µm on the surface of the nitrogen-polar face per unit area can be reduced to, for example, 0.01 to 3 per 1 mm². The above-described number of foreign substances per unit area is preferably 0.01 to 1 per 1 mm² when the obtained aluminum nitride single crystal substrate is used as a base substrate in the method for producing an aluminum nitride single crystal layered body to be described later in view of efficiently suppressing formation of pits in the nitrogen-polar face. In this description, the number (number density) of foreign substances having a longer diameter of no less than 10 µm on the surface of the nitrogen-polar face of the aluminum nitride single crystal substrate per unit area can be measured as follows. On the nitrogen-polar face of the substrate, three points in the vertical direction × three points in the horizontal direction, total nine measurement points including the center of the substrate are set. FIG. 9 schematically illustrates the arrangement of the nine measurement points on the substrate, and shows the nine measurement points superposed on a plan view of a first aluminum nitride single crystal substrate 10. While FIG. 9 describes the first aluminum nitride single crystal substrate 10 as an example of the substrate, the measurement points are set in the same manner for any other substrate. Three reference lines Row 1, Row 2, and Row 3 are arranged in parallel in this order at regular intervals d; and three reference lines Col 1, Col 2, and Col 3 are arranged in parallel in this order at the regular intervals d so as to be orthogonal to the reference lines Row 1 to Row 3. Nine points of intersection of the reference lines Row 1 to Row 3, and the reference lines Col 1 to Col 3, that is, P11, P12, P13, P21, P22, P23, P31, P32, and P33 are defined as measurement points. The reference lines Row 1 to Row 3 and Col 1 to Col 3 are arranged in such a manner that the point of intersection of the reference line Row 2 and the reference line Col 2, that is, P22 is at the center point of the substrate. The interval d is kept as wide as possible, as long as the distance from each of the measurement points other than P22 to the circumference of the substrate is within the range of no less than 3 mm. The actual interval d can be, for example, 5 mm to 20 mm according to the size of the substrate. For each of the measurement points, the field of 4.87 mm² (1.91 mm×2.55 mm) is observed by means of a Nomarski differential interference contrast microscope (ECLIPSE (registered trademark) LVDIA-N manufactured by NIKON CORPORATION) with an object lens with a magnifying power of 5. For the observation, each of the set measurement points is put at the center of the field. In the observation image of each of the measurement points, the number of foreign substances having a longer diameter of no less than 10 µm is counted. The numbers of the foreign substances observed at the nine measurement points are averaged to calculate the number of the foreign substances per 1 mm² in area.

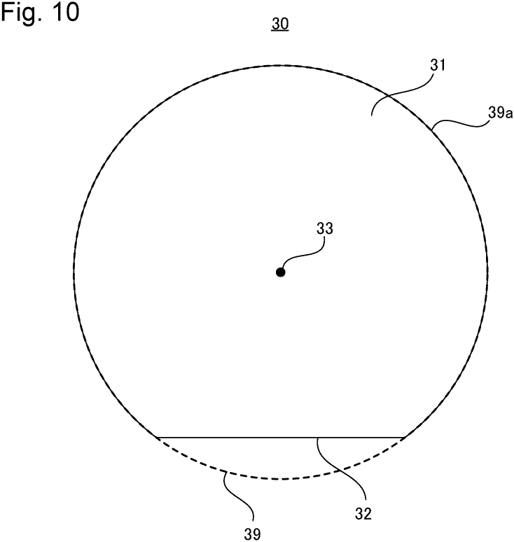

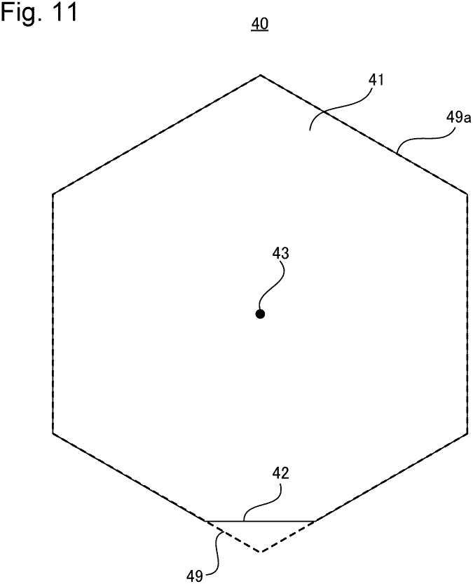

In one embodiment, the planar shape of the aluminum nitride single crystal substrate (that is, the shape of the nitrogen-polar face) can be a circle, or a regular polygon, or a partially distorted circle or regular polygon (for example, a partially cut circle, and a partially cut regular polygon). When the number of foreign substances having a longer diameter of no less than 10 µm on the surface of the nitrogen-polar face of the aluminum nitride single crystal substrate per unit area is measured, the position of the center of the substrate is obvious when the planar shape of the substrate displays rotation symmetry (for example, a circle or a regular polygon), and is the position of the rotating axis of symmetry. However, the aluminum nitride single crystal substrate may be provided with, for example, an orientation flat (notch) for showing the direction of a crystallographic axis: strictly speaking, this notch causes the rotation symmetry of the substrate to be lost. In this description, when the rotation symmetry of the planar shape of the substrate is lost, the position of the center of the substrate shall be determined as follows. FIG. 10 illustrates the center of the substrate when the planar shape of the substrate is a partially distorted circle, with a plan view of an aluminum nitride single crystal substrate 30 according to another embodiment (hereinafter may be referred to as the “substrate 30”). The substrate 30 has a peripheral part 32. The substrate 30 is a so-called partially cut circular substrate having an orientation flat; and the planar shape of the substrate 30 is a partially distorted circle. The planar shape of the substrate 30 does not display rotation symmetry since partially distorted from a circle. An “original circle” 39 of the planar shape of the substrate 30 can be found as a circle 39 having the longest total length of a section 39a that is part of the circumference thereof and overlaps the peripheral part 32 of the substrate 30. A center 33 of the original circle 39 is the center of the substrate 30. FIG. 11 illustrates the center of the substrate when the planar shape of the substrate is a partially distorted regular polygon, with a plan view of an aluminum nitride single crystal substrate 40 according to another embodiment (hereinafter may be referred to as the “substrate 40”). The substrate 40 has a peripheral part 42. The substrate 40 is a so-called partially cut regular hexagonal substrate having an orientation flat; and the planar shape of the substrate 40 is a partially distorted regular hexagon. The planar shape of the substrate 40 does not display rotation symmetry since partially distorted from a regular hexagon. An “original regular hexagon” 49 of the planar shape of the substrate 40 can be found as a regular hexagon 49 having the longest total length of a section 49a that is part of the circumference thereof and overlaps the peripheral part 42 of the substrate 40. A center 43 of the original regular hexagon 49 is the center of a main face 41.

When weakly acid, neutral, or weakly alkaline water or aqueous solution having a pH of 4 to 10 is used as the above scrubbing liquid, the etching of the nitrogen-polar face of the aluminum nitride single crystal substrate with the washing liquid in the scrubbing step S11 can be suppressed. For example, the surface roughness (arithmetic average roughness Ra) of the nitrogen-polar face after the washing method S10 is completed can be 1 to 8 nm. Here, the surface roughness (arithmetic average roughness Ra) of the nitrogen-polar face can be measured by means of a white-light interferometric microscope. In this description, the measurement of the surface roughness (arithmetic average roughness Ra) of the aluminum nitride single crystal substrate by means of a white-light interferometric microscope can be performed according to the following procedures. The field range (58800 µm² (280 µm×210 µm)) set at the center of the substrate is observed by means of a white-light interferometric microscope (NewView (registered trademark) 7300 manufactured by Zygo Corporation) with an object lens with a magnifying power of 50. The white-light interferometric microscope (NewView (registered trademark) 7300 manufactured by Zygo Corporation) has a function of automatically measuring and calculating the surface roughness of a field range. The arithmetic average roughness Ra can be automatically measured and calculated along a measurement line that is automatically set at the center of the field.

### 2. Method for Producing Aluminum Nitride Single Crystal Layered Body (1)

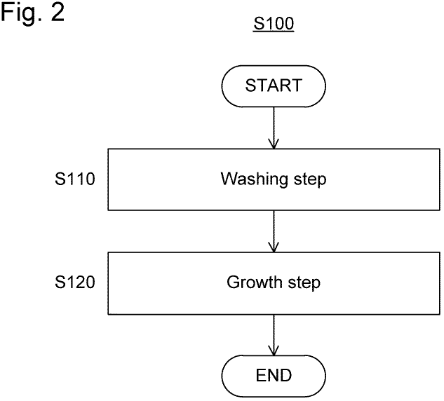

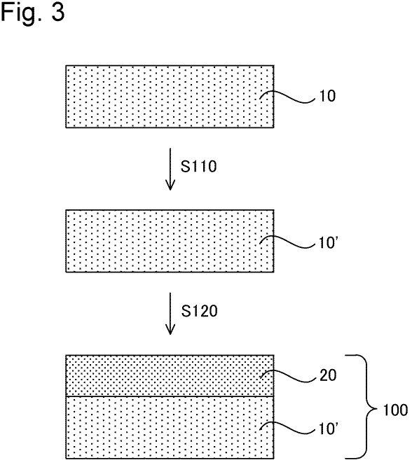

FIG. 2 is a flowchart illustrating a method S100 for producing an aluminum nitride single crystal layered body according to another embodiment of the present invention (hereinafter may be referred to as the “layered body production method S100” or the “production method S100”). FIG. 3 schematically illustrates the production method S100 with cross sections. The layered body production method S100 comprises: in the sequence set forth: the step S110 of (b) washing the first aluminum nitride single crystal substrate 10 by the washing method S10 (see FIG. 1) (hereinafter may be referred to as the “washing step S110”); and the step S120 of (c) growth a first aluminum nitride single crystal layer 20 over a first base substrate 10′ by a vapor phase epitaxy method, wherein a first aluminum nitride single crystal substrate 10′ after the (b) is used as the first base substrate 10′ (hereinafter may be referred to as the “growth step S120”). An aluminum nitride single crystal layered body 100 having an opposite face (nitrogen-polar face) where formation of pits is suppressed (hereinafter may be referred to as the “first aluminum nitride single crystal layered body 100” or the “first layered body 100” or the “layered body 100”) can be produced by: depositing the aluminum nitride single crystal layer 20 over the base substrate 10′ by a vapor phase epitaxy method, wherein the aluminum nitride single crystal substrate 10′ obtained by the washing method S10 is used as the base substrate.

### Washing Step S110

The washing step S110 is a step of washing the first aluminum nitride single crystal substrate 10 by the washing method S10 (see FIG. 1). The details of the washing method S10 are as described above. In the layered body production method S100, the aluminum nitride single crystal substrate described above as a substrate of a raw material in the washing method S10 can be used as the first aluminum nitride single crystal substrate 10; and a preferred aspect of the first aluminum nitride single crystal substrate 10 is also the same as described above.

### Growth Step S120

The growth step S120 is a step of growing the first aluminum nitride single crystal layer 20 over the first base substrate 10′ by a vapor phase epitaxy method, wherein the first aluminum nitride single crystal substrate 10′ after the washing step 110 is used as the first base substrate 10′. In the growth step S120, preferably, the first aluminum nitride single crystal layer 20 is grown over an aluminum-polar face of the first base substrate 10′. As a means for growing the aluminum nitride single crystal layer over the aluminum-polar face of the base substrate 10′, any known vapor phase epitaxy method such as HVPE, MOCVD, and MBE can be employed without particular limitations.

The first aluminum nitride single crystal layer 20 can be grown by HVPE by: supplying an aluminum halide gas and a nitrogen source gas that are raw material gases onto the heated base substrate in a reactor in a state where the gases are each diluted by a carrier gas; and reacting both the gasses on the heated base substrate 10′. As the aluminum halide gas herein, aluminum chloride gas can be preferably used. The aluminum halide gas can be obtained by bringing high-purity metal aluminum having a purity of no less than 99.9999% and high-purity hydrogen chloride gas or high-purity chlorine gas having a purity of no less than 99.999% into contact with each other. As the nitrogen source gas herein, ammonia gas is preferably used. As the carrier gas herein, any known gas as a carrier gas having a dew point controlled to be no more than -110° C., such as dry hydrogen, nitrogen, argon, and helium can be preferably used. A hydrogen halide gas such as hydrogen chloride is also allowed to coexist with each of the raw material gases. The heating temperature of the base substrate, the supply amounts of the aluminum halide gas and the nitrogen source gas, and the linear velocities of the supplied gasses are factors influencing the crystal growth rate, and can be suitably determined according to the desired crystal growth rate. The temperature of the base substrate while the first aluminum nitride single crystal layer 20 is grown by HVPE is usually 1200° C. to 1800° C., preferably 1350° C. to 1700° C., and more preferably 1450° C. to 1600° C. As a means for heating the substrate, any known heating means such as resistance heating, high-frequency induction heating, and optical heating can be used. As the means for heating the substrate, one heating means may be used alone, or two or more heating means may be used in combination.

Concerning the supply amounts of the raw material gases, the supply amount of the aluminum halide gas can be, for example, 0.001 sccm to 500 sccm; and the supply amount of the nitrogen source gas can be 0.01 sccm to 5000 sccm. For arranging the gas flows inside the reactor, it is effective to promote discharge from the reactor, as well as to dispose a dry pump on the downstream side of a device to keep the pressure inside the reactor fixed. The pressure inside the reactor is preferably 100 Torr to 1000 Torr, and more preferably 360 Torr to 760 Torr.

When it is necessary to control the electroconductivity of the first aluminum nitride single crystal layer 20, the aluminum nitride single crystal layer 20 can be grown as impurities (such as compounds containing Si, Mg, S, etc.) that function as a donor or an acceptor are supplied.

When the first aluminum nitride single crystal layer 20 is grown by a sublimation method, on one side of a crucible for growth that is disposed inside a reactor, the first base substrate 10′ is fixed; and on the other side of the crucible (position facing the base substrate), an aluminum nitride polycrystal raw material is arranged. The first base substrate 10′ side and the raw material side are made to have a temperature gradient therebetween in a nitrogen atmosphere, and thereby, the aluminum nitride polycrystal raw material is vaporized, to deposit an aluminum nitride single crystal over the first base substrate 10′. As the material of the crucible herein, tungsten, tantalum carbide, or the like is generally used. The growth temperature in the growth by a sublimation method is usually 1800° C. to 2300° C.; and the pressure in the reactor is usually 100 Torr to 1000 Torr. As the aluminum nitride polycrystal raw material herein, a polycrystal raw material that was subjected to refining operation of removing impurities by using the effects of sublimation and recrystallization in advance is preferably used.

The first aluminum nitride single crystal layered body 100 obtained through the growing step S120 comprises the first base substrate 10′, and the first aluminum nitride single crystal layer 20 layered over the aluminum-polar face of the first base substrate 10′ (FIG. 3). The layered body 100 can be preferably used as a substrate for producing a group III nitride semiconductor device after, for example, the growth surface is mirror-polished with a polishing means such as polishing by CMP.

### 3. Method for Producing Aluminum Nitride Single Crystal Substrate, and Method for Producing Aluminum Nitride Single Crystal Layered Body (2)

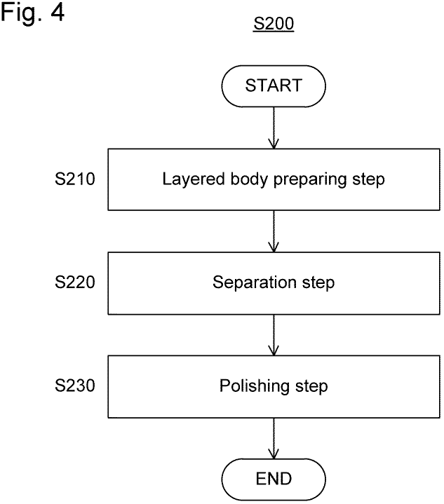

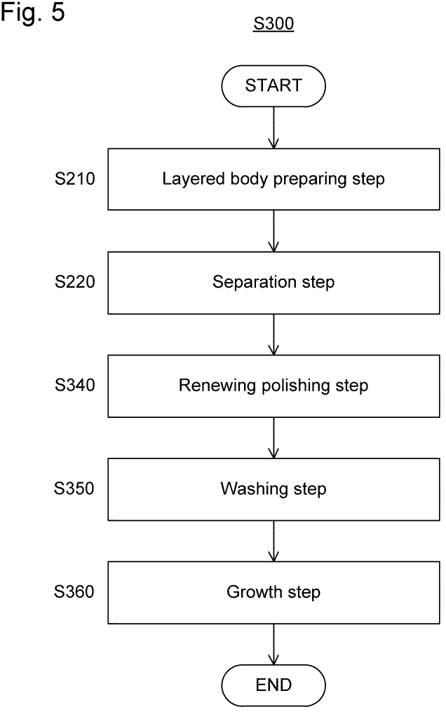

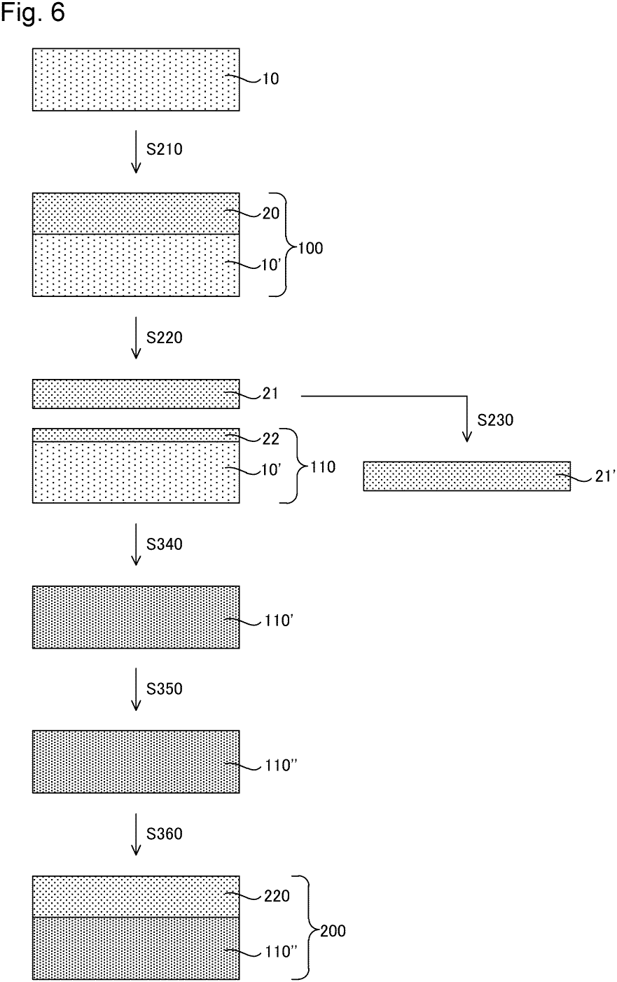

FIG. 4 is a flowchart illustrating a method S200 for producing an aluminum nitride single crystal substrate according to one embodiment of the present invention (hereinafter may be referred to as the “substrate production method S200” or the “production method S200”). FIG. 5 is a flowchart illustrating a method S300 for producing an aluminum nitride single crystal layered body according to another embodiment of the present invention (hereinafter may be referred to as the “layered body production method S300” or the “production method S300”). FIG. 6 schematically illustrates the production methods S200 and S300 with cross sections. The substrate production method S200 comprises, in the sequence set forth: the step S210 of (d) obtaining the first aluminum nitride single crystal layered body 100 by the layered body production method S100 (FIG. 2) (hereinafter may be referred to as the “layered body preparing step S210”); the step S220 of (e) separating the first aluminum nitride single crystal layered body 100 into a second base substrate 110 and a second aluminum nitride single crystal layer 21, wherein the second base substrate 110 comprises at least part of the first base substrate 10′, and wherein the second aluminum nitride single crystal layer 21 comprises at least part of the first aluminum nitride single crystal layer 20 (hereinafter may be referred to as the “separation step S220”); and the step S230 of (f) polishing the second aluminum nitride single crystal layer 21, to obtain a second aluminum nitride single crystal substrate 21′ (hereinafter may be referred to as the “polishing step S230”). The second aluminum nitride single crystal substrate 21′ can be used for producing a group III nitride semiconductor device.

### Layered Body Preparing Step S210

The layered body preparing step S210 is a step of obtaining the first aluminum nitride single crystal layered body 100 by the layered body production method S100 (FIG. 2). The details of the layered body production method S100 are as described above. Too thin a thickness of the first aluminum nitride single crystal layer 20 grown in the growing step S120 of the layered body production method S100 (FIG. 2) leads to a thin second aluminum nitride single crystal substrate (aluminum nitride single crystal self-supporting substrate) 21′ obtained in the separation step S220 to be described later, which leads to a tendency for the second aluminum nitride single crystal substrate 21′ to easily break due to insufficient strength when the second aluminum nitride single crystal substrate 21′ is processed to be a wafer for producing a device by a process such as peripheral grinding and polishing. Therefore, the thickness of the first aluminum nitride single crystal layer 20 grown in the growth step S120 is preferably no less than 500 µm, more preferably 600 to 1500 µm, and further preferably 800 to 1200 µm.

### Separation Step S220

The separation step S220 is a step of cutting the first layered body 100 obtained in the layered body preparing step S210, and thereby, separating the layered body 100 into the second base substrate 110 and the second aluminum nitride single crystal layer 21, wherein the second base substrate 110 comprises at least part of the first base substrate 10′, and wherein the second aluminum nitride single crystal layer 21 comprises at least part of the first aluminum nitride single crystal layer 20. A layer having strained on the crystal surface (strained layer) is formed, by the cutting, on the cut face of the aluminum nitride single crystal substrate after the separation step S220. When the strained layer remains on the aluminum nitride single crystal substrate, the crystal quality of an aluminum nitride single crystal layer (growth layer) to be grown over the aluminum nitride single crystal substrate may deteriorate, and/or residual stress may cause cracks in the aluminum nitride single crystal layer (growth layer). Thus, the strained layer is removed in the renewing polishing step to be described later. Therefore, in the separation step S220, preferably, a thin film 22 that is at least part of the first aluminum nitride single crystal layer 20 is left on the base substrate 10′ as an extra space for formation of the strained layer, or for removal of the strained layer. That is, the second base substrate 110 obtained by the separation step S220 preferably comprises the first base substrate 10′, and the part 22 of the first aluminum nitride single crystal layer (20) layered over the first base substrate 10′.

The thickness of the thin film 22 of the aluminum nitride single crystal layer, which remains on the separated second base substrate 110 is not particularly limited, but is preferably 5 µm to 300 µm in view of removing the strained layer in the renewing polishing step S340 to be described later.

The cutting in the separation step S220 is carried out in parallel to the growth surface of the base substrate 10′. When a wire saw is used in the separation step S220, a wire saw of either fixed or free abrasive grains may be used. Preferably, the tension of the wire herein is adjusted so that the thickness of an extra space for the cutting is thin, for example, approximately 100 to 300 µm.

The cutting speed of the wire saw is adjusted so that the strained layer (damaged layer) remaining on the cut surface of the aluminum nitride single crystal layer is thin. A relatively low speed is preferable for the condition for the cutting speed. The cutting speed is preferably within the range of 0.5 mm/h to 20 mm/h.

The wire in the cutting may be moved so as to swing. The wire may be successively or intermittently moved in the cutting direction. The swinging movement of the wire during the cutting is properly controlled so as to prevent cracks from being formed due to heat generated by friction in the cutting. An example of intermittently moving the wire in the cutting direction is that the following operation is repeated: the wire is moved in the cutting direction, the movement of the wire in the cutting direction is once stopped if the wire bends, and the wire is moved in the cutting direction again after the bending of the wire is dissolved, since the wire bends when the speed at which the wire is moved in the cutting direction and the speed at which the aluminum nitride single crystal is actually cut do not the same.

For suppressing crack formation accompanying chipping of the periphery of the base substrate in the cutting, one may cover the entire or part of the layered body 100 with a protective material such as a resin, any of waxes, and any of cements prior to the separation step S220, and thereafter, perform the cutting. As the resin herein, a common resin such as epoxy resins, and phenolic resins can be used. When the resin is used as the protective material herein, the layered body 100 can be cut after the resin is cured by a common curing means such as curing by self-drying, thermosetting, and photo-setting after the layered body 100 is covered with the resin. As the cement herein, common industrial Portland cement, aluminous cement, gypsum, or the like can be used.

When cut in the cutting step, the layered body 100 itself may be revolved. The speed of the revolution of the layered body is preferably within the range of 1 rpm to 10 rpm.

### Polishing Step S230

The polishing step S230 is a step of polishing the second aluminum nitride single crystal layer 21 obtained in the separation step S220, to obtain the second aluminum nitride single crystal substrate 21′. As a polishing means in the polishing step S230, for example, any known polishing means such as polishing by CMP can be used without particular restrictions. The second aluminum nitride single crystal substrate 21′ can be preferably used as a substrate for producing a group III nitride semiconductor device.

After the separated surface is processed to be an ultra-flat face by polishing by CMP and the nitrogen-polar face is scrubbed to remove foreign substances on the nitrogen-polar face, the second base substrate 110 separated in the separation step S220 can be iteratively reused as a base substrate for depositing a new aluminum nitride single crystal. When the base substrate for an aluminum nitride single crystal is iteratively reused, for example, the method disclosed in patent literature 4 can be employed.

### Method for Iteratively Reusing Aluminum Nitride Single Crystal Substrate as Base Substrate

The method for iteratively reusing the aluminum nitride single crystal substrate as a base substrate comprises the renewing polishing step of polishing the surface of the second base substrate obtained in the separation step, and the repetition step of growing an aluminum nitride single crystal over the polished surface of the second base substrate after the renewing polishing step.

FIG. 5 shows the method S300 for producing an aluminum nitride single crystal layered body according to such another embodiment. The layered body production method S300 comprises, in the sequence set forth: the step S210 of (d) obtaining the first aluminum nitride single crystal layered body 100 by the layered body production method S100 (layered body preparing step S210); the step S220 of (e) separating the first aluminum nitride single crystal layered body 100 into the second base substrate 110 and the second aluminum nitride single crystal layer 21, wherein the second base substrate 110 comprises at least part of the first base substrate 10′, and wherein the second aluminum nitride single crystal layer 21 comprises at least part of the first aluminum nitride single crystal layer 20 (separation step S220); the step S340 of (g) polishing the surface of the second base substrate 110 (hereinafter may be referred to as the “renewing polishing step S340”); the step S350 of (h) washing, by the washing method S10, a second base substrate 110′ after the step S340 (hereinafter may be referred to as the “washing step S350”); and the step S360 of (i) growing a third aluminum nitride single crystal substrate 220 over a second base substrate 110″ after the steps S340 and S350 by a vapor phase epitaxy method (hereinafter may be referred to as the “growth step S360”). The details of the layered body preparing step S210 and the separation step S220 are as described above concerning the substrate production method S200 (FIG. 4).

### Renewing Polishing Step S340

The renewing polishing step S340 is a step of polishing the surface of the cut face of the second base substrate 110 obtained in the separation step S220. Through the renewing polishing step S340, the aluminum nitride single crystal substrate (renewed base substrate) 110′, which can be used as a base substrate for crystal growth again, is obtained.

For removing, in the renewing polishing step S340, the strained layer present on the second base substrate 110 obtained in the cutting step S220, the surface of the cut face of the separated second base substrate 110 is preferably polished by more than 10 µm, more preferably polished by no less than 30 µm, and further preferably polished by no less than 100 µm therefrom. The more the polishing amount is, the more the strained layer can be removed. However, a more polishing amount leads to higher industrial costs. Thus, the polishing amount is preferably no more than 600 µm, more preferably no more than 200 µm, and further preferably no more than 100 µm. The presence or not of the strained layer can be evaluated by a half width of an X-ray omega rocking curve of a (103) face which is measured under a condition that an incident angle between an incident X-ray and the aluminum-polar face of the aluminum nitride single crystal substrate after the renewing polishing is no more than 4°. This half width is preferably no more than 200 arcsec. The incident angle between the incident X-ray and the aluminum-polar face of the aluminum nitride single crystal substrate after the renewing polishing is more preferably no more than 2°. In view of current measurement techniques, the lower limit of the incident angle between the incident X-ray and the aluminum-polar face is 0.1°. The X-ray omega rocking curve of the above-described crystal face more preferably has a half width of no more than 100 arcsec, and further preferably has a half width of no more than 80 arcsec. The half width is preferably no less than 10 arcsec. In the measurement of the X-ray omega rocking curve of the specific crystal face, an X-ray source monochromated by being diffracted twice by the (220) face of a germanium single crystal is preferably used.

For removing the strained layer formed in the cutting in the separation step S220, the renewing polishing step is preferably completed by chemical mechanical polishing (CMP). CMP can be performed by a known method. As an abrasive herein, any abrasive containing a material such as silica, alumina, ceria, silicon carbide, boron nitride, and diamond can be used. The properties of the abrasive may be alkaline, neutral, or acidic. Since alkali resistance of a nitrogen-polar face ((00-1) face) of aluminum nitride is low, a weakly alkaline, neutral or acidic abrasive, specifically an abrasive of no more than 9 in pH is more preferably used than a strong alkaline abrasive. A strong alkaline abrasive can be used of course without any problem when a protection film is formed on the nitrogen-polar face. An additive such as an oxidizing agent can be incorporated into the abrasive for improving the polishing rate. A commercially available polishing pad can be used as a polishing pad herein, and material and hardness thereof are not specifically restricted.

The polishing in the renewing polishing step S340 may be carried out by, for example, CMP from the beginning to the end. For example, when the aluminum nitride thin film layer 22 included in the second base substrate 110 after the separation step S220 is thick, CMP may be carried out after the thickness is adjusted in advance to be approximately a desired thickness by a means having a high polishing rate such as mirror finish lapping.

The properties of the second base substrate 110′ after the renewing polishing step S340 are almost the same as the original aluminum single crystal substrate. Therefore, the crystal quality (the half width of the X-ray omega rocking curve and the dislocation density) of the second base substrate 110′ after the renewing polishing step S340 can be equal to the crystal quality (the half width of the X-ray omega rocking curve and the dislocation density) of the original aluminum nitride single crystal substrate (first aluminum nitride single crystal substrate) 10. When the offset angle of the surface of the second base substrate 110′ after the renewing polishing step S340 differs from a desired angle, an offset angle adjusting polishing step for adjusting the offset angle of the aluminum-polar face of the second base substrate 110′ after the renewing polishing step S340 to be a desired offset angle may be further carried out.

### Washing Step S350

The washing step S350 is a step of washing, by the washing method S10, the second base substrate 110′ after the renewing polishing step S340 (FIG. 1). The details of the washing method S10 are as described above. The second base substrate 110″, from which foreign substances on the nitrogen-polar face thereof is removed, can be obtained by scrubbing at least the nitrogen-polar face of the second base substrate 110′ after the renewing polishing step S340 according to the present invention.

### Growth Step S360

The growth step S360 is a step of growing, by a vapor phase epitaxy method, the third aluminum nitride single crystal layer 220 over the second base substrate 110″ after the separation step S340 and the renewing polishing step S350. The growth step S360 can be performed in the same manner as the growth step S120 described above concerning the production method S100 (FIG. 2); and a preferred aspect thereof is also the same as described above. As well as the second aluminum nitride single crystal layer 20 described above concerning the layered body preparing step S210, the thickness of the third aluminum nitride single crystal layer 220 grown in the growth step S360 is preferably no less than 500 µm, more preferably 600 to 1500 µm, and further preferably 800 to 1200 µm. Through the growth step S360, the second aluminum nitride single crystal layered body 200 is obtained (FIG. 6). The second aluminum nitride single crystal layered body 200 comprises the second base substrate 110″, and the third aluminum nitride single crystal layer 220 layered over the aluminum-polar face of the second base substrate 110″.

The above description concerning the present invention shows the substrate production method S200 and the layered body production method S300 wherein the second base substrate 110 obtained in the separation step S220 comprises the first base substrate 10′, and the part 22 of the first aluminum nitride single crystal layer 20 layered over the first base substrate 10′ (that is, in the separation step S220, the first aluminum nitride single crystal layered body 100 is cut, so that the part 22 of the first aluminum nitride single crystal layer 20 is left on the first base substrate 10′) as an example. The present invention is not limited to this embodiment. For example, the method for producing an aluminum nitride single crystal substrate, and the method for producing an aluminum nitride single crystal layered body can comprise, in the separation step S220, cutting the first aluminum nitride single crystal layered body 100 with no part of the first aluminum nitride single crystal layer 20 left on the first base substrate 10′, and separating the layered body 100 into the second base substrate and the second aluminum nitride single crystal substrate.

The second aluminum nitride single crystal layered body 220 can be preferably used as a substrate for producing a group III nitride semiconductor device after, for example, the growth surface is mirror-polished with a polishing means such as polishing by CMP. For example, the second aluminum nitride single crystal layered body 200 may be regarded as a first aluminum nitride single crystal layered body of the next generation (the layered body preparing step S210), to carry out the separation step S220, the renewing polishing step S340, the washing step S350, and the growth step S360 again (repetition step). The repetition step may be iteratively carried out.

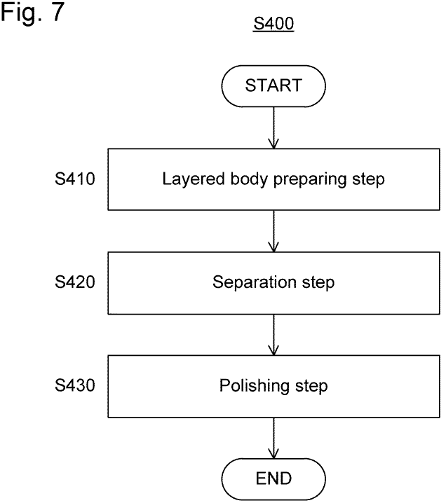

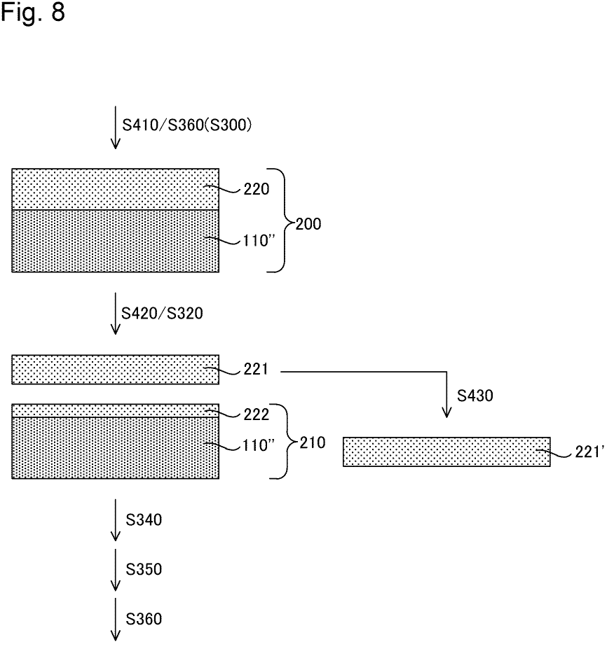

In the repetition step, a further new aluminum nitride single crystal substrate can be obtained from the second aluminum nitride single crystal layered body 200. FIG. 7 is a flowchart illustrating a method S400 for producing an aluminum nitride single crystal substrate according to such another embodiment (hereinafter may be referred to as the “substrate production method S400” or the “production method S400”). FIG. 8 schematically illustrates the production method S400 with cross sections. The substrate production method S400 comprises, in the sequence set forth: the step S410 of (j) obtaining the second aluminum nitride single crystal layered body 200 by the production method S300 (hereinafter may be referred to as the “layered body preparing step S410”); the step S420 of (k) separating the second aluminum nitride single crystal layered body 200 into a third base substrate 210 and a fourth aluminum nitride single crystal layer 221, wherein the third base substrate 210 comprises at least part of the second base substrate 110″, and wherein the fourth aluminum nitride single crystal layer 221 comprises at least part of the third aluminum nitride single crystal layer 220 (hereinafter may be referred to as the “separation step S420”); and the step S430 of (1) polishing the fourth aluminum nitride single crystal layer 221, to obtain a third aluminum nitride single crystal substrate 221′ (hereinafter may be referred to as the “polishing step S430”).

The layered body production method S300 (FIG. 5) has been described in detail already. The separation step S420 can be carried out in the same manner as the above described separation step S220 concerning the substrate production method S200 and the layered body production method S300 except that the first aluminum nitride single crystal layered body 100 is replaced with the second aluminum nitride single crystal layered body 200, the first base substrate 10′ is replaced with the second base substrate 110″, and the first aluminum nitride single crystal layer 20 is replaced with the third aluminum nitride single crystal layer 220; and a preferred aspect thereof is also the same as described above. For example, in the separation step S420, preferably, a thin film 222 that is at least part of the third aluminum nitride single crystal layer 220 is left on the second base substrate 110″. That is, the third base substrate 210 obtained by the separation step S420 preferably comprises the second base substrate 110″, and the part 222 of the second aluminum nitride single crystal layer (220) layered over the first base substrate 110″.

The polishing step S430 can be carried out in the same manner as the above-described polishing step S230 concerning the substrate production method S200 and the layered body production method S300 except that the second aluminum nitride single crystal layer 21 is replaced with the fourth aluminum nitride single crystal layer 221; and a preferred aspect thereof is also the same as described above. The third aluminum nitride single crystal substrate 221′ can be preferably used as a substrate for producing a group III nitride semiconductor device.

The above description concerning the present invention shows the methods S200 and S400 each for producing an aluminum nitride single crystal substrate comprising: obtaining one aluminum nitride single crystal substrate (21′/221′) from the aluminum nitride single crystal layer (growth layer) (20/220) of the aluminum nitride single crystal layered body (100/200), as an example. The present invention is not limited to this embodiment. For example, the method for producing an aluminum nitride single crystal substrate can comprise cutting out two or more aluminum nitride single crystal substrates from the aluminum nitride single crystal layer (growth layer) of the layered body.

### EXAMPLES

Hereinafter the present invention will be described in more detail with reference to examples. The present invention is not limited to these examples. The expression % hereinafter means vol% unless otherwise specified.

In the following examples and comparative examples, the number (number density) of foreign substances on the surface of the nitrogen-polar face per unit area, the surface roughness (arithmetic average roughness Ra) of the nitrogen-polar face, and the pit density of the nitrogen-polar face were calculated by the following measurement methods.

### Method for Measuring Number (Number Density) of Foreign Substances on Surface of Nitrogen-Polar Face Per Unit Area

On the nitrogen-polar face of the substrate, three points in the vertical direction times three points in the horizontal direction, total nine measurement points including the center of the substrate were set. FIG. 9 schematically illustrates the arrangement of the nine measurement points on the substrate, and shows the nine measurement points superposed on a plan view of a first aluminum nitride single crystal substrate 10. While FIG. 9 describes the first aluminum nitride single crystal substrate 10 as an example of the substrate, the measurement points are set in the same manner for any other substrate. Three reference lines Row 1, Row 2, and Row 3 were arranged in parallel in this order at regular intervals d; and three reference lines Col 1, Col 2, and Col 3 were arranged in parallel in this order at the regular intervals d so as to be orthogonal to the reference lines Row 1 to Row 3. Nine points of intersection of the reference lines Row 1 to Row 3, and the reference lines Col 1 to Col 3, that is, P11, P12, P13, P21, P22, P23, P31, P32, and P33 were defined as measurement points. The reference lines Row 1 to Row 3 and Col 1 to Col 3 were arranged in such a manner that the point of intersection of the reference line Row 2 and the reference line Col 2, that is, P22 was at the center point of the substrate. The interval d was kept as wide as possible, as long as the distance from each of the measurement points other than P22 to the circumference of the substrate was within the range of no less than 3 mm. The actual interval d was 5 mm to 20 mm according to the size of the substrate. For each of the measurement points, the field of 4.87 mm² (1.91 mm×2.55 mm) was observed by means of a Nomarski differential interference contrast microscope (ECLIPSE (registered trademark) LVDIA-N manufactured by NIKON CORPORATION) with an object lens with a magnifying power of 5. For the observation, each of the set measurement points was put at the center of the field. In the observation image of each of the measurement points, the number of foreign substances having a longer diameter of no less than 10 µm was counted. The numbers of the foreign substances observed at the nine measurement points were averaged to calculate the number of the foreign substances per 1 mm² in area.

### Method for Measuring Surface Roughness (Arithmetic Average Roughness Ra) of Nitrogen-Polar Face

The field range (58800 µm² (280 µm×210 µm)) set at the center of the substrate was observed by means of a white-light interferometric microscope (NewView (registered trademark) 7300 manufactured by Zygo Corporation) with an object lens with a magnifying power of 50. The white-light interferometric microscope (NewView (registered trademark) 7300 manufactured by Zygo Corporation) has a function of automatically measuring and calculating the surface roughness of a field range. The arithmetic average roughness Ra was automatically measured and calculated along a measurement line that is automatically set at the center of the field.

### Method for Measuring Pit Density of Nitrogen-Polar Face

The pit density was calculated by: observing the entire nitrogen-polar face by means of a Nomarski differential interference contrast microscope (ECLIPSE (registered trademark) LVDIA-N manufactured by NIKON CORPORATION) and counting the total number of the pits having a longer diameter of no less than 100 µm; and dividing the total number of the pits by the area of the nitrogen-polar face.

The aluminum nitride single crystal substrates used in the following examples and comparative examples were aluminum nitride single crystal substrates prepared by a sublimation method: both the aluminum-polar face and the nitrogen-polar face of each thereof were polished by CMP to be mirror faces. The shapes of the obtained aluminum nitride single crystal substrates were each 25.4 mm to 50.8 mm in outer diameter, and approximately 500 µm in thickness. After the polishing by CMP, various evaluations were carried out on the aluminum nitride single crystal substrates not in a clean room but in a general environment where cleanliness was not managed. Thus, a large amount of foreign substances etc. present in the environment were adhered to the surfaces of the substrates.

### Example 1

An aluminum nitride single crystal substrate having an outer diameter of 35.0 mm was prepared. The number (number density) of foreign substances having a longer diameter of no less than 10 µm on the surface of a nitrogen-polar face of this aluminum nitride single crystal substrate per unit area measured 3.35 pcs/mm² according to the above-described method. The surface roughness (arithmetic average roughness Ra) of the surface of the nitrogen-polar face of this aluminum nitride single crystal substrate measured 3.32 nm according to the above-described method.

The aluminum nitride single crystal substrate was put on melamine foam absorbing ultrapure water in such a manner that the aluminum-polar face thereof faced downwards. Then, ultrapure water was poured from a washing bottle over the entire nitrogen-polar face of the aluminum nitride single crystal substrate for 5 seconds. Thereafter, a washing liquid was poured from a washing bottle over the entire nitrogen-polar face of the aluminum nitride single crystal substrate as well for 3 seconds. As the washing liquid, a 1% diluted solution of CLEANTHROUGH (registered trademark) KS-3053 manufactured by Kao Corporation with ultrapure water was used. The pH of the diluted solution was 8.0.

Cut melamine foam in the form of a cube 30 mm square was immersed in ultrapure water that was drawn in a clean container, to absorb the water, and thereafter, was bought into contact with the surface of the nitrogen-polar face of the aluminum nitride single crystal substrate. This melamine foam was moved in one direction parallel to the surface of the substrate as being in contact with the surface of the nitrogen-polar face, so that the surface of the nitrogen-polar face of the aluminum nitride single crystal substrate was scrubbed therewith. The surface of the nitrogen-polar face was scrubbed 25 times in total as the position where the melamine foam was in contact therewith was changed so that the melamine foam was in contact with the entire surface of the nitrogen-polar face of the aluminum nitride single crystal substrate. After the scrubbing, a washing liquid was poured from a washing bottle over the entire nitrogen-polar face of the aluminum nitride single crystal substrate for 3 seconds, and the nitrogen-polar face of the aluminum nitride single crystal substrate was scrubbed further 25 times with melamine foam immersed in ultrapure water to absorb the water in the same manner as the above. After the scrubbing, ultrapure water as a rinse was poured from a washing bottle over the entire nitrogen-polar face of the aluminum nitride single crystal substrate for 5 seconds. By the above-described steps, the nitrogen-polar face of the aluminum nitride single crystal substrate was scrubbed.

Next, the aluminum-polar face of the aluminum nitride single crystal substrate was scrubbed by means of a wafer cleaning system (NAMIKI-ECCLEAR manufactured by Adamant Namiki Precision Jewel Co., Ltd.). The aluminum nitride single crystal substrate was put on the system in such a manner that the aluminum-polar face thereof was a top face, and the scrubbing was performed by an automatic program. Specifically, ultrapure water was poured onto the surface of the substrate (aluminum-polar face), and thereafter, both a scrubbing step, and a rinsing step with ultrapure water were repeated twice, to dry the substrate by spin drying. The scrubbing was performed by scrubbing the aluminum-polar face of the aluminum nitride single crystal substrate with a rotating nylon brush as pouring, onto the surface of the substrate (aluminum-polar face), a 1% diluted solution (pH 8.0) of CLEANTHROUGH (registered trademark) KS-3053 manufactured by Kao Corporation with ultrapure water as a washing liquid.

The number (number density) of foreign substances having a longer diameter of no less than 10 µm on the obtained surface of the nitrogen-polar face of the aluminum nitride single crystal substrate per unit area measured 0.14 pcs/mm² according to the above-described method.

The surface roughness (arithmetic average roughness Ra) of the obtained surface of the nitrogen-polar face of the aluminum nitride single crystal substrate measured 3.93 nm according to the above-described method.

### Example 2

The same operation as in example 1 was performed except that the washing liquid used for scrubbing the nitrogen-polar face and the aluminum-polar face of the aluminum nitride substrate was changed to a 10% diluted solution (pH 9.0) of CLEANTHROUGH (registered trademark) KS-3053 manufactured by Kao Corporation with ultrapure water.

The number (number density) of foreign substances having a longer diameter of no less than 10 µm on a surface of a nitrogen-polar face of the obtained aluminum nitride single crystal substrate per unit area measured 0.07 pcs/mm² according to the above-described method.

The surface roughness (arithmetic average roughness Ra) of the surface of the nitrogen-polar face of the obtained aluminum nitride single crystal substrate measured 5.82 nm according to the above-described method.

### Example 3

The same operation as in example 1 was performed except that the washing liquid used for scrubbing the nitrogen-polar face and the aluminum-polar face of the aluminum nitride substrate was changed to CLEANTHROUGH (registered trademark) KS-3053 manufactured by Kao Corporation (pH 10.0).

The number (number density) of foreign substances having a longer diameter of no less than 10 µm on a surface of a nitrogen-polar face of the obtained aluminum nitride single crystal substrate per unit area measured 0.11 pcs/mm² according to the above-described method.

The surface roughness (arithmetic average roughness Ra) of the surface of the nitrogen-polar face of the obtained aluminum nitride single crystal substrate measured 5.55 nm according to the above-described method.

### Example 4

The same operation as in example 1 was performed except that the washing liquid used for scrubbing the nitrogen-polar face and the aluminum-polar face of the aluminum nitride substrate was changed to ultrapure water (pH 7.0).

The number (number density) of foreign substances having a longer diameter of no less than 10 µm on a surface of a nitrogen-polar face of the obtained aluminum nitride single crystal substrate per unit area measured 0.14 pcs/mm² according to the above-described method.

The surface roughness (arithmetic average roughness Ra) of the surface of the nitrogen-polar face of the obtained aluminum nitride single crystal substrate measured 3.53 nm according to the above-described method.

### Example 5

The same operation as in example 1 was performed except that the washing liquid used for scrubbing the nitrogen-polar face and the aluminum-polar face of the aluminum nitride substrate was changed to a 1% diluted solution (pH 11.4) of Sanwash (registered trademark) TL-75 manufactured by Lion Specialty Chemicals Co., Ltd. with ultrapure water.

The number (number density) of foreign substances having a longer diameter of no less than 10 µm on a surface of a nitrogen-polar face of the obtained aluminum nitride single crystal substrate per unit area measured 0.27 pcs/mm² according to the above-described method.

The surface roughness (arithmetic average roughness Ra) of the surface of the nitrogen-polar face of the obtained aluminum nitride single crystal substrate measured 8.81 nm according to the above-described method.

### Example 6

The same operation as in example 1 was performed except that the washing liquid used for scrubbing the nitrogen-polar face and the aluminum-polar face of the aluminum nitride substrate was changed to a 2% diluted solution (pH 11.7) of Sanwash (registered trademark) TL-75 manufactured by Lion Specialty Chemicals Co., Ltd. with ultrapure water.

The number (number density) of foreign substances having a longer diameter of no less than 10 µm on a surface of a nitrogen-polar face of the obtained aluminum nitride single crystal substrate per unit area measured 0.30 pcs/mm² according to the above-described method.

The surface roughness (arithmetic average roughness Ra) of the surface of the nitrogen-polar face of the obtained aluminum nitride single crystal substrate measured 9.64 nm according to the above-described method.

### Example 7

The same operation as in example 1 was performed except that the washing liquid used for scrubbing the nitrogen-polar face and the aluminum-polar face of the aluminum nitride substrate was changed to a 10% diluted solution (pH 12.4) of Sanwash (registered trademark) TL-75 manufactured by Lion Specialty Chemicals Co., Ltd. with ultrapure water.

The number (number density) of foreign substances having a longer diameter of no less than 10 µm on a surface of a nitrogen-polar face of the obtained aluminum nitride single crystal substrate per unit area measured 0.27 pcs/mm² according to the above-described method.

The surface roughness (arithmetic average roughness Ra) of the surface of the nitrogen-polar face of the obtained aluminum nitride single crystal substrate measured 11.11 nm according to the above-described method.

### Example 8

Dilute hydrochloric acid having a pH of 3.0 was prepared by diluting 35 mass% hydrochloric acid with ultrapure water. This dilute hydrochloric acid was added to 1 L of a 1% diluted solution of CLEANTHROUGH (registered trademark) KS-3053 manufactured by Kao Corporation with ultrapure water, and thereby, a washing liquid for scrubbing which had an adjusted pH of 6.0 was prepared. The same operation as in example 1 was performed except that the washing liquid used for scrubbing the nitrogen-polar face and the aluminum-polar face of the aluminum nitride substrate was changed to this prepared solution (pH 6.0).

The number (number density) of foreign substances having a longer diameter of no less than 10 µm on a surface of a nitrogen-polar face of the obtained aluminum nitride single crystal substrate per unit area measured 0.52 pcs/mm² according to the above-described method.

The surface roughness (arithmetic average roughness Ra) of the surface of the nitrogen-polar face of the obtained aluminum nitride single crystal substrate measured 5.05 nm according to the above-described method.

### Example 9

The same operation as in example 8 was performed except that the amount of the added dilute hydrochloric acid was changed in such a manner that the washing liquid for the scrubbing had a pH of 5.0.

The number (number density) of foreign substances having a longer diameter of no less than 10 µm on a surface of a nitrogen-polar face of the obtained aluminum nitride single crystal substrate per unit area measured 0.27 pcs/mm² according to the above-described method.

The surface roughness (arithmetic average roughness Ra) of the surface of the nitrogen-polar face of the obtained aluminum nitride single crystal substrate measured 5.95 nm according to the above-described method.

### Example 10

The same operation as in example 8 was performed except that the amount of the added dilute hydrochloric acid was changed in such a manner that the washing liquid for the scrubbing had a pH of 4.0.

The number (number density) of foreign substances having a longer diameter of no less than 10 µm on a surface of a nitrogen-polar face of the obtained aluminum nitride single crystal substrate per unit area measured 0.82 pcs/mm² according to the above-described method.

The surface roughness (arithmetic average roughness Ra) of the surface of the nitrogen-polar face of the obtained aluminum nitride single crystal substrate measured 6.38 nm according to the above-described method.

### Example 11

The same operation as in example 8 was performed except that the amount of the added dilute hydrochloric acid was changed in such a manner that the washing liquid for the scrubbing had a pH of 3.3.

The number (number density) of foreign substances having a longer diameter of no less than 10 µm on a surface of a nitrogen-polar face of the obtained aluminum nitride single crystal substrate per unit area measured 0.71 pcs/mm² according to the above-described method.

The surface roughness (arithmetic average roughness Ra) of the surface of the nitrogen-polar face of the obtained aluminum nitride single crystal substrate measured 8.39 nm according to the above-described method.

The results of the examples 1 to 11 were summarized as in table 1.

TABLE 1

| AlN substrate | pH of washing liquid | Nitrogen-polar face | |
|---|---|---|---|
| | | Number density of foreign substances (pcs/mm²) | Surface roughness Ra (nm) |
| before washing | - | 3.35 | 3.32 |
| example 1 | 8.0 | 0.14 | 3.93 |
| example 2 | 9.0 | 0.07 | 5.82 |
| example 3 | 10.0 | 0.11 | 5.55 |
| example 4 | 7.0 | 0.14 | 3.53 |
| example 5 | 11.4 | 0.27 | 8.81 |
| example 6 | 11.7 | 0.30 | 9.64 |
| example 7 | 12.4 | 0.27 | 11.11 |
| example 8 | 6.0 | 0.52 | 5.05 |
| example 9 | 5.0 | 0.27 | 5.95 |
| example 10 | 4.0 | 0.82 | 6.38 |
| example 11 | 3.3 | 0.71 | 8.39 |

### Example 12

An aluminum nitride single crystal substrate having an outer diameter of 50.8 mm (2 inches) was prepared. Before washing, the number (number density) of foreign substances having a longer diameter of no less than 10 µm on the surface of the nitrogen-polar face of the aluminum nitride single crystal substrate per unit area was 4.33 pcs/mm²; and the surface roughness (arithmetic average roughness Ra) of the surface of the nitrogen-polar face was 1.60 nm. The nitrogen-polar face and the aluminum-polar face of the aluminum nitride single crystal substrate were washed by the same way as in example 1 (washing step). After the washing step, the number (number density) of foreign substances having a longer diameter of no less than 10 µm on the surface of the nitrogen-polar face per unit area was 0.64 pcs/mm²; and the surface roughness (arithmetic average roughness Ra) of the surface of the nitrogen-polar face was 2.10 nm. An aluminum nitride single crystal layer was layered by HVPE over the obtained aluminum nitride single crystal substrate as a base substrate (growth step). Specifically, the washed aluminum nitride single crystal substrate (base substrate) was disposed on a susceptor in an HVPE apparatus provided with a heating mechanism by high-frequency induction heating in such a manner that the aluminum-polar face was a top face. Under the conditions that the heating temperature of the substrate was 1450° C., and the pressure inside a reactor was 500 Torr, 30 sccm of an aluminum trichloride gas, 250 sccm of an ammonia gas, and a nitrogen gas and a hydrogen gas as carrier gasses were circulated to grow an aluminum nitride single crystal layer having a thickness of approximately 450 to 500 µm over the aluminum-polar face of the aluminum nitride single crystal substrate (base substrate) for 8 hours, so that an aluminum nitride single crystal layered body was obtained.

The pit density of the nitrogen-polar face of the obtained aluminum nitride single crystal layered body was calculated by the above-described method, and the result thereof was 0.052 pcs/mm².

### Example 13

An aluminum nitride single crystal substrate having an outer diameter of 25.4 mm (1 inch) was prepared. Before washing, the number (number density) of foreign substances having a longer diameter of no less than 10 µm on the surface of the nitrogen-polar face of the aluminum nitride single crystal substrate per unit area was 3.26 pcs/mm²; and the surface roughness (arithmetic average roughness Ra) of the surface of the nitrogen-polar face was 1.78 nm. The nitrogen-polar face and the aluminum-polar face of the aluminum nitride single crystal substrate were washed by the same way as in example 1 (washing step). After the washing, the number (number density) of foreign substances having a longer diameter of no less than 10 µm on the surface of the nitrogen-polar face per unit area was 0.78 pcs/mm²; and the surface roughness (arithmetic average roughness Ra) of the surface of the nitrogen-polar face was 2.10 nm. An aluminum nitride single crystal layer was layered by HVPE over the obtained aluminum nitride single crystal substrate as a base substrate (growth step). Specifically, the washed aluminum nitride single crystal substrate (first base substrate) was disposed on a susceptor in an HVPE apparatus provided with a heating mechanism by high-frequency induction heating in such a manner that the aluminum-polar face was a top face. Under the conditions that the heating temperature of the substrate was 1450° C., and the pressure inside a reactor was 500 Torr, 12 sccm of an aluminum trichloride gas, 60 sccm of an ammonia gas, and a nitrogen gas and a hydrogen gas as carrier gasses were circulated to grow a first aluminum nitride single crystal layer (HVPE growth layer) having a thickness of approximately 800 to 1000 µm over the aluminum-polar face of the aluminum nitride single crystal substrate (first base substrate) for 16 hours, so that an aluminum nitride single crystal layered body was obtained.

The obtained aluminum nitride single crystal layered body cut with a wire saw, and thereby, was separated into a second base substrate comprising: the first base substrate; and part of the first aluminum nitride single crystal layer (HVPE growth layer) layered over the first base substrate, and the other part of the first aluminum nitride single crystal layer (HVPE growth layer) (second aluminum nitride single crystal layer) (separation step). Specifically, the layered body was separated by moving the wire saw in parallel to the aluminum-polar face of the base substrate along such a place that the HVPE growth layer was left on the first base substrate by 120 µm in thickness. Renewing polishing was performed on the second base substrate by grinding and polishing, by CMP, the separated second base substrate on the aluminum-polar face side (renewing polishing step). The HVPE growth layer having a thickness of 30 µm was left on the second base substrate after the renewing polishing step.

The nitrogen-polar face and the aluminum-polar face of the second base substrate after the renewing polishing was washed by the same way as in example 1 (washing step). An aluminum nitride single crystal layer was grown over the washed aluminum-polar face of the base substrate under the same conditions as described above (growth step). The obtained layered body was separated into a base substrate and an HVPE growth layer under the same conditions as described above (separation step), and renewing polishing was performed on the base substrate (renewing polishing step). After a series of these steps (repetition step; i.e., the washing step, the growing step, the separation step, and the renewing polishing step) was iterated seven times, the base substrate was further washed by the same way as in example 1, and an aluminum nitride single crystal layer was grown over the base substrate by HVPE. As a result, no cracking in the base substrate or faults in crystal growth caused by the base substrate occurred.

### Comparative Example 1

An aluminum nitride single crystal layered body was prepared in the same manner as in example 12 except that the nitrogen-polar face of the aluminum nitride single crystal substrate was not scrubbed. Before washing, the number (number density) of foreign substances having a longer diameter of no less than 10 µm on the surface of the nitrogen-polar face per unit area was 4.02 pcs /mm²; and the surface roughness (arithmetic average roughness Ra) of the surface of the nitrogen-polar face was 1.80 nm. After washing, the number (number density) of foreign substances having a longer diameter of no less than 10 µm on the surface of the nitrogen-polar face per unit area was 3.02 pcs/mm²; and the surface roughness (arithmetic average roughness Ra) of the surface of the nitrogen-polar face was 2.07 nm.

The pit density of the nitrogen-polar face of the obtained aluminum nitride single crystal layered body was calculated by the above-described method, and the result thereof was 0.256 pcs/mm².

### Reference Example

An aluminum nitride single crystal substrate having an outer diameter of 25.4 mm (1 inch) was washed in the same manner as in example 1 except that the nitrogen-polar face thereof was not scrubbed. Before washing, the number (number density) of foreign substances having a longer diameter of no less than 10 µm on the surface of the nitrogen-polar face per unit area was 5.38 pcs/mm²; and the surface roughness (arithmetic average roughness Ra) of the surface of the nitrogen-polar face was 1.60 nm. After washing, the number (number density) of foreign substances having a longer diameter of no less than 10 µm on the surface of the nitrogen-polar face per unit area was 3.10 pcs/mm²; and the surface roughness (arithmetic average roughness Ra) of the surface of the nitrogen-polar face was 1.82 nm. An aluminum nitride single crystal layer (HVPE growth layer) having a thickness of approximately 800 to 1000 µm was grown by HVPE over the aluminum-polar face of the substrate (first base substrate) for 16 hours under the same conditions as in example 13 (growth step).

The obtained aluminum nitride single crystal layered body was cut with a wire saw, and thereby, was separated into a second base substrate comprising: the first base substrate; and part of the HVPE growth layer layered over the first base substrate, and the other part of the HVPE growth layer (separation step). Specifically, the layered body was separated by moving the wire saw in parallel to the aluminum-polar face of the base substrate along such a place that the HVPE growth layer was left on the first base substrate by 100 µm in thickness. Renewing polishing was performed on the second base substrate by grinding and polishing, by CMP, the separated second base substrate on the aluminum-polar face side (renewing polishing step). The renewing polishing step caused the HVPE growth layer over the first base substrate to be lost. The original base substrate (first base substrate) was exposed on the aluminum-polar face of the second base substrate after the renewing polishing.

The repetition step (the washing step, the growing step, the separation step, and the renewing polishing step) was iterated using the second base substrate after the renewing polishing in the same manner as in example 13. After this repetition step was iterated four times, the aluminum-polar face of the base substrate was observed by means of a Nomarski differential interference contrast microscope. As a result, plural pits penetrating from the opposite face (that is, the nitrogen-polar face) to the surface (that is, the aluminum-polar face) of the base substrate were observed. No such through pits were observed in the observation of the aluminum-polar face of the base substrate after the repetition step was iterated three times. Therefore, it is considered that the iteration of the repetition step extended the pits from the nitrogen-polar face to the aluminum-polar face, and finally allowed the pits to penetrate through. The fifth repetition step with the base substrate caused the base substrate to fracture in the renewing polishing step. This is considered to be because the presence of through pits as described above in the substrate led to strained, so that the substrate fractured.

### Comparative Example 2

An aluminum nitride single crystal substrate having an outer diameter of 25.4 mm (1 inch) was washed in the same manner as in example 1 except that the nitrogen-polar face thereof was not scrubbed. Before washing, the number (number density) of foreign substances having a longer diameter of no less than 10 µm on the surface of the nitrogen-polar face per unit area was 5.38 pcs/mm²; and the surface roughness (arithmetic average roughness Ra) of the surface of the nitrogen-polar face was 1.60 nm. After washing, the number (number density) of foreign substances having a longer diameter of no less than 10 µm on the surface of the nitrogen-polar face per unit area was 3.10 pcs/mm²; and the surface roughness (arithmetic average roughness Ra) of the surface of the nitrogen-polar face was 1.82 nm. An aluminum nitride single crystal layer (HVPE growth layer) having a thickness of approximately 800 to 1000 µm was grown over the aluminum-polar face of the substrate (first base substrate) for 16 hours under the same conditions as in example 13, so that an aluminum nitride single crystal layered body was obtained.

The obtained aluminum nitride single crystal layered body was cut with a wire saw, and thereby was separated into a second base substrate comprising: the first base substrate; and part of the HVPE growth layer layered over the first base substrate, and the other part of the HVPE growth layer (separation step). Specifically, the layered body was separated by moving the wire saw in parallel to the aluminum-polar face of the base substrate along such a place that the HVPE growth layer was left on the base substrate by 100 µm in thickness. Renewing polishing was performed on the second base substrate by grinding and polishing, by CMP, the separated second base substrate on the aluminum-polar face side (renewing polishing step). The renewing polishing step caused the HVPE growth layer over the first base substrate to be lost. The original base substrate (first base substrate) was exposed on the aluminum-polar face of the second base substrate after the renewing polishing.

The repetition step (the washing step of the aluminum-polar face of the substrate, the growing step, the separation step, and the renewing polishing step) was iterated using the second base substrate after the renewing polishing in the same manner as in example 13 except that the nitrogen-polar face was not scrubbed in any of the washing steps. After this repetition step was iterated twice, the aluminum-polar face of the base substrate was observed by means of a Nomarski differential interference contrast microscope. As a result, plural pits penetrating from the opposite face (that is, the nitrogen-polar face) to the surface (that is, the aluminum-polar face) of the base substrate were observed. On the aluminum-polar face of the base substrate after the repetition step was iterated three times, it was observed that these pits were enlarged to be 250 mm in width and 200 µm in depth at the maximum. When an aluminum nitride single crystal layer was grown over the aluminum-polar face of the base substrate by HVPE, abnormal growth occurred at the places of the pits.

REFERENCE SIGNS LIST

| | |
|---|---|
| 10 | first aluminum nitride single crystal substrate |
| 10′ | first base substrate |
| 20 | first aluminum nitride single crystal layer (growth layer) |
| 21 | part of the first aluminum nitride single crystal layer |
| 21′ | second aluminum nitride single crystal substrate |
| 22 | other part of the first aluminum nitride single crystal layer |
| 100 | first aluminum nitride single crystal layered body |
| 110, 110′, 110″ | second base substrate |
| 200 | second aluminum nitride single crystal layered body |
| 210 | third base substrate |
| 220 | third aluminum nitride single crystal layer (growth layer) |
| 221 | part of the third aluminum nitride single crystal layer |
| 221′ | third aluminum nitride single crystal substrate |
| 222 | other part of third aluminum nitride single crystal layer |
| 30, 40 | aluminum nitride single crystal substrate |
| 31, 41 | nitrogen-polar face |
| Row 1, Row 2, Row 3 | (lateral) reference line |
| Col 1, Col 2, Col 3 | (longitudinal) reference line |
| Pij (i and j are each an integer of 1 to 3) | measurement point |

1. A method for washing an aluminum nitride single crystal substrate, the aluminum nitride single crystal substrate comprising:
an aluminum-polar face; and
a nitrogen-polar face opposite to the aluminum-polar face, the method comprising:
(a) scrubbing a surface of the nitrogen-polar face.

2. The method according to claim 1,
the (a) comprising:
making a polymer material absorb a washing liquid, wherein the polymer material is less hard than the aluminum nitride single crystal; and
scrubbing the surface of the nitrogen-polar face with the polymer material retaining the washing liquid.

3. The method according to claim 2,
wherein water or an aqueous solution each having a pH of 4 to 10 is used as the washing liquid in the (a).

4. A method for producing an aluminum nitride single crystal layered body, the method comprising, in the sequence set forth:
(b) washing a first aluminum nitride single crystal substrate by the method as defined in claim 1; and
(c) growing a first aluminum nitride single crystal layer over a first base substrate by a vapor phase epitaxy method, wherein the first aluminum nitride single crystal substrate is used as the first base substrate.

5. The method according to claim 4,
wherein the first aluminum nitride single crystal layer is grown, in the (c), over an aluminum-polar face of the first base substrate.

6. A method for producing an aluminum nitride single crystal substrate, the method comprising, in the sequence set forth:
(d) obtaining a first aluminum nitride single crystal layered body by the method as defined in claim 4;
(e) separating the first aluminum nitride single crystal layered body into a second base substrate and a second aluminum nitride single crystal layer, wherein the second base substrate comprises at least part of the first base substrate, and wherein the second aluminum nitride single crystal layer comprises at least part of the first aluminum nitride single crystal layer; and
(f) polishing the second aluminum nitride single crystal layer, to obtain a second aluminum nitride single crystal substrate.

7. The method according to claim 6,
wherein the second base substrate in the (e) comprises:
the first base substrate; and
part of the first aluminum nitride single crystal layer layered over the first base substrate.

8. A method for producing an aluminum nitride single crystal layered body, the method comprising, in the sequence set forth:
(d) obtaining a first aluminum nitride single crystal layered body by the method as defined in claim 4;
(e) separating the first aluminum nitride single crystal layered body into a second base substrate and a second aluminum nitride single crystal layer, wherein the second base substrate comprises at least part of the first base substrate, and wherein the second aluminum nitride single crystal layer comprises at least part of the first aluminum nitride single crystal layer;
(g) polishing a surface of the second base substrate;
(h) washing the second base substrate by the method for washing an aluminum nitride single crystal substrate,
the aluminum nitride single crystal substrate comprising:
an aluminum-polar face; and
a nitrogen-polar face opposite to the aluminum-polar face,
the method comprising:
(a) scrubbing a surface of the nitrogen-polar face; and
(i) growing a third aluminum nitride single crystal substrate over the second base substrate by a vapor phase epitaxy method.

9. The method according to claim 8,
wherein the second base substrate in the (e) comprises:
the first base substrate; and
part of the first aluminum nitride single crystal layer layered over the first base substrate.

10. The method according to claim 8,
wherein the third aluminum nitride single crystal layer is grown, in the (i), over an aluminum-polar face of the second base substrate.

11. A method for producing an aluminum nitride single crystal substrate, the method comprising, in the sequence set forth:
(j) obtaining a second aluminum nitride single crystal layered body by the method as defined in claim 8;
(k) separating the second aluminum nitride single crystal layered body into a third base substrate and a fourth aluminum nitride single crystal layer, wherein the third base substrate comprises at least part of the second base substrate, and wherein the fourth aluminum nitride single crystal layer comprises at least part of the third aluminum nitride single crystal layer; and
(1) polishing the fourth aluminum nitride single crystal layer, to obtain a third aluminum nitride single crystal substrate.

12. The method according to claim 11,
wherein the third base substrate in the (k) comprises:
the second base substrate; and
part of the third aluminum nitride single crystal layer layered over the second base substrate.

13. An aluminum nitride single crystal substrate comprising:
an aluminum-polar face; and
a nitrogen-polar face opposite to the aluminum-polar face,
wherein a number density of foreign substances having a longer diameter of no less than 10 µm on a surface of the nitrogen-polar face per unit area is 0.01 to 3 pcs/mm².

14. The aluminum nitride single crystal substrate according to claim 13,
wherein the nitrogen-polar face has a surface roughness of 1 to 8 nm in terms of arithmetic average roughness Ra.
